(19) United States
(12) Patent Application Publication
(10) Pub. No.: US 2026/0282566 A1
(43) Pub. Date: Sep. 17, 2026

(54) TWO-DIMENSIONAL PHOTOSENSOR AND MANUFACTURING METHOD OF TWO-DIMENSIONAL PHOTOSENSOR

(71) Applicant: Kepler Corp., Tokyo (JP)

(72) Inventors: Yoshitoshi KIDA, Tokyo (JP); Hiroyuki OSHIMA, Tokyo (JP); Kosho TSUBOI, Tokyo (JP); Takahiro ISHINABE, Tokyo (JP); Yasuhide HOSODA, Tokyo (JP); Kalil KALANTAR, Tokyo (JP); Yutaka OSHIMA, Tokyo (JP); Patrick SCHALBERGER, Stuttgart (DE)

(21) Appl. No.: 19/165,861

(22) PCT Filed: Mar. 14, 2024
(86) PCT No.: PCT/JP2024/010044

§ 371 Date: Sep. 16, 2025

(30) Foreign Application Priority Data
Mar. 16, 2023 (JP) 2023-042021

(51) Int. Cl. H10F 39/10; H10F 30/227; H10F 71/00; H10F 71/10; H10F 77/00; H10F 77/122; H10F 77/166

(52) U.S. Cl. CPC H10F 39/103; H10F 30/2275; H10F 39/107; H10F 71/103; H10F 77/122; H10F 77/1662; H10F 77/957; H10F 71/138

(57) ABSTRACT

The present invention provides a two-dimensional photosensor which can be manufactured at a low cost in a thin film transistor factory and extends over a relatively wide two-dimensional plane. This two-dimensional photosensor comprises a plurality of arrayed photodiodes. The photodiodes each have a laminate of a first metal electrode, a first semiconductor layer, a first ohmic contact layer, and a first transparent electrode. The first semiconductor layer and the first ohmic contact layer are arranged between the first metal electrode and the first transparent electrode. This two-dimensional photosensor has a Schottky barrier at the interface between the first semiconductor layer and the first metal electrode, or at the interface between the first semiconductor layer and the first transparent electrode, and senses light incident thereon from the first transparent electrode side toward the first semiconductor layer.

### TECHNICAL FIELD

The present invention relates to a two-dimensional photosensor and a manufacturing method of a two-dimensional photosensor.

### BACKGROUND ART

Conventionally, two-dimensional photosensors have been used in photographing devices, fingerprint authentication devices, etc. The two-dimensional photosensor has photodiodes which are responsive to light. A plurality of the photodiodes are arranged lengthwise and widthwise. As the photodiodes, for example, PIN-type semiconductor elements such as in solar cells can be used. As a semiconductor layer, for example, an amorphous silicon (hereinafter a-Si) layer has been used. An example applying a two-dimensional photosensor to a fingerprint sensor has been disclosed in Patent Document 1 described below.

### CITATION LIST

### Patent Document

Patent Document 1: Japanese Unexamined Patent Application, Publication No. 2017-194676

### DISCLOSURE OF THE INVENTION

### Problems to be Solved by the Invention

Patent Document 1 discloses an optical fingerprint sensor. The optical fingerprint sensor scans a high-resolution fingerprint pattern in a small area on the order of a fingertip. The configuration used in the fingerprint sensor is not suited to applications detecting a natural light distribution over a region wider than the fingerprint region. For example, the detection of a natural light distribution over the entire display surface is an example thereof. As the display, an organic EL display is assumed, for example. In the organic EL display, a PIN-type junction used in fingerprint sensors is not being used. In the case of applying the configuration of a fingerprint sensor to an organic EL display, a semiconductor layer constituting the PIN-type junction which is not in a conventional constituent element is additionally provided to the entire display surface. However, it is difficult to evenly provide a PIN-type amorphous (a-Si) photodiode (PD) to the wide area possessed by a display. On the other hand, in the case of detecting a natural light distribution over a relatively wide two-dimensional space such as a display, a high-density sensor arrangement such as a fingerprint sensor is unnecessary.

In the case of applying the two-dimensional photosensor to a device having a relatively wide area such as a display, the necessity to curb cost is even higher. The PIN-type diode is high cost, and a plant which can produce PIN-type configurations must be selected. The compatibility with the manufacturing process of thin-film transistors is low, and thus the sharing of processes is difficult.

The present invention has an object of providing a two-dimensional photosensor which can be produced inexpensively in a thin-film transistor plant, and can detect over a relatively wide two-dimensional plane.

### Means for Solving the Problems

A two-dimensional photosensor includes a plurality of arrayed photodiodes, in which the photodiodes each include a laminate of a first metal electrode; a first semiconductor layer; a first ohmic contact layer; and a first transparent electrode, in which the first semiconductor layer and the first ohmic contact layer are arranged between the first metal electrode and the first transparent electrode, a Schottky barrier is provided at an interface between the first semiconductor layer and the first metal electrode, or at an interface between the first semiconductor layer and the first transparent electrode, and the photosensor senses light incident from a side of the first transparent electrode toward the first semiconductor layer.

In the two-dimensional photosensor, the first semiconductor layer consists of amorphous silicon, and the first ohmic contact layer consists of n+amorphous silicon.

In the two-dimensional photosensor, the first metal electrode has a light shielding property, and includes a configuration extending out of a light sensing region.

In the two-dimensional photosensor, photoelectric current of each of the photodiodes is individually acquired through direct connection, or acquired by scanning through a simple matrix system.

The two-dimensional photosensor further includes a readout circuit that reads a signal of the photodiode, in which the readout circuit includes a thin film transistor, and the thin film transistor includes at least one layer consisting of a layer which is the same as a layer constituting the photodiode.

In the two-dimensional photosensor, the thin film transistor includes a second metal electrode, the second metal electrode functions as a gate electrode of the thin film transistor, and the second metal electrode consists of a layer which is the same as the first metal electrode of the photodiode, and is not electrically connected with the first metal electrode.

In the two-dimensional photosensor, the thin film transistor includes a source electrode and a drain electrode, and the source electrode and the drain electrode at least include a layer which is the same as the first transparent electrode possessed by the photodiode or the first metal electrode.

In the two-dimensional photosensor, the thin film transistor includes a second semiconductor layer, and the second semiconductor layer consists of a layer which is the same as a first semiconductor layer possessed by the photodiode.

In the two-dimensional photosensor, the thin film transistor includes a second semiconductor layer consisting of an indium gallium zinc oxide.

In the two-dimensional photosensor, the photodiode includes a dielectric layer which reduces surface reflection at an outermost surface on a side opposite to a glass substrate.

In a manufacturing method of a two-dimensional photosensor, the two-dimensional photosensor including a plurality of arrayed photodiodes, and a readout circuit of signals from the photodiodes, the photodiodes each including a laminate of a first metal electrode, a first semiconductor layer, a first ohmic contact layer, and a first transparent electrode, in which the first semiconductor layer and the first ohmic contact layer are arranged between the first metal electrode and the first transparent electrode, a Schottky barrier is provided at an interface between the first semiconductor layer and the first metal electrode, or at an interface between the first semiconductor layer and the first transparent electrode, the photosensor senses light incident from a side of the first transparent electrode toward the first semiconductor layer, and the signal readout circuit includes a thin film transistor, the method including a step of simultaneously forming at least one layer constituting the photodiode and the thin film transistor.

In a manufacturing method of a two-dimensional photosensor, the thin film transistor includes: a gate electrode; a second semiconductor layer; a second ohmic contact layer; a source electrode and a drain electrode, the method including at least any one step among: a metal electrode film forming step of simultaneously forming the first metal electrode and the gate electrode, or a metal electrode film forming step of simultaneously forming the first metal electrode, the source electrode and the drain electrode; a semiconductor layer film forming step of simultaneously forming the first semiconductor layer and the second semiconductor layer; an ohmic contact layer film forming step of simultaneously forming the first ohmic contact layer and the second ohmic contact layer; and a transparent electrode film forming step of simultaneously forming the first transparent electrode, the source electrode and the drain electrode.

In the manufacturing method of a two-dimensional photosensor, the first semiconductor layer contains amorphous silicon, and the first ohmic contact layer contains n+ amorphous silicon.

In a manufacturing method of a two-dimensional photosensor, a first semiconductor layer contains an amorphous silicon layer, a first ohmic contact layer contains an n+ amorphous silicon layer, a thin film transistor includes: a second metal electrode arranged on a glass substrate, and functioning as a gate electrode; a second semiconductor layer consisting of an IGZO layer; and a second transparent electrode arranged on the second semiconductor layer, and functioning as a source electrode and a drain electrode, the manufacturing method of a two-dimensional photosensor including: a metal electrode film forming step of simultaneously forming the first metal electrode and the second metal electrode; and a transparent electrode film forming step of simultaneously forming the first transparent electrode and the second transparent electrode.

### Effects of the Invention

The present invention provides a two-dimensional photosensor capable of gradation detection over a relatively wide two-dimensional plane.

### BRIEF DESCRIPTION OF THE DRAWINGS

FIG. 1 is an overall circuit diagram of a two-dimensional photosensor according to a first embodiment of the present invention;

FIG. 2 is a view showing an example of characteristics of a photodiode according to the first embodiment of the present invention;

FIG. 3 is a schematic diagram showing an output signal from a gate driver, an output signal from a signal processing circuit, and an input signal to the signal processing circuit according to the first embodiment of the present invention;

FIG. 4 is a plan view of a photosensing portion according to the first embodiment of the present invention;

FIG. 5 is a cross-sectional view of a photodiode according to the first embodiment of the present invention;

FIG. 6 is a cross-sectional view of a photosensing portion according to the first embodiment of the present invention;

FIG. 7 is a cross-sectional view of one manufacturing step of a photosensing portion according to the first embodiment of the present invention;

FIG. 8 is a cross-sectional view of one manufacturing step of a photosensing portion according to the first embodiment of the present invention;

FIG. 9 is a cross-sectional view of one manufacturing step of a photosensing portion according to the first embodiment of the present invention;

FIG. 10 is a cross-sectional view of one manufacturing step of a photosensing portion according to the first embodiment of the present invention;

FIG. 11 is a cross-sectional view of one manufacturing step of a photosensing portion according to the first embodiment of the present invention;

FIG. 12 is a cross-sectional view of one manufacturing step of a photosensing portion according to the first embodiment of the present invention;

FIG. 13 is a cross-sectional view of one manufacturing step of a photosensing portion according to the first embodiment of the present invention;

FIG. 14 is a cross-sectional view of one manufacturing step of a photosensing portion according to the first embodiment of the present invention;

FIG. 15 is a plan view of a photosensing portion according to a first modified example of the present invention;

FIG. 16 is a cross-sectional view of a photosensing portion according to the first modified example of the present invention;

FIG. 17 is a cross-sectional view of a photosensing portion according to a second embodiment of the present invention;

FIG. 18 is a cross-sectional view of one manufacturing step of a photosensing portion according to the second embodiment of the present invention;

FIG. 19 is a cross-sectional view of one manufacturing step of a photosensing portion according to the second embodiment of the present invention;

FIG. 20 is a cross-sectional view of one manufacturing step of a photosensing portion according to the second embodiment of the present invention;

FIG. 21 is a cross-sectional view of one manufacturing step of a photosensing portion according to the second embodiment of the present invention;

FIG. 22 is a cross-sectional view of one manufacturing step of a photosensing portion according to the second embodiment of the present invention;

FIG. 23 is a cross-sectional view of one manufacturing step of a photosensing portion according to the second embodiment of the present invention;

FIG. 24 is a cross-sectional view of one manufacturing step of a photosensing portion according to the second embodiment of the present invention;

FIG. 25 is a cross-sectional view of a photodiode according to a second modified example of the present invention;

FIG. 26 is a plan view of a photodiode according to a third modified example of the present invention;

FIG. 27 is a cross-sectional view of the photodiode according to the third modified example of the present invention;

FIG. 28 is a cross-sectional view of a photodiode according to a fourth modified example of the present invention;

FIG. 29 is a schematic diagram showing a relationship between a photodiode and a signal processing circuit according to the fourth modified example of the present invention;

FIG. 30 is a cross-sectional view of a photodiode according to a fifth modified example of the present invention;

FIG. 31 is a cross-sectional view of a photodiode according to a sixth modified example of the present invention;

FIG. 32 is a cross-sectional view of a photodiode according to a seventh modified example of the present invention;

FIG. 33 is an overall circuit diagram of a two-dimensional photosensor according to an eighth modified example of the present invention;

FIG. 34 is a plan view of a photosensing portion according to the eighth modified example of the present invention;

FIG. 35 is a cross-sectional view of a photosensing portion according to the eighth modified example of the present invention; and

FIG. 36 is an overall circuit diagram of a two-dimensional photosensor according to a ninth modified example of the present invention.

### PREFERRED MODE FOR CARRYING OUT THE INVENTION

Hereinafter, a two-dimensional photosensor 100 according to a first embodiment of the present invention will be described while referencing the drawings. It should be noted that the same reference numbers are attached to constituent elements which are the same in each of the drawings. When discriminating an identical constituent element as in a first constituent element and a second constituent element, a, b, etc. will be attached to the reference number.

### First Embodiment

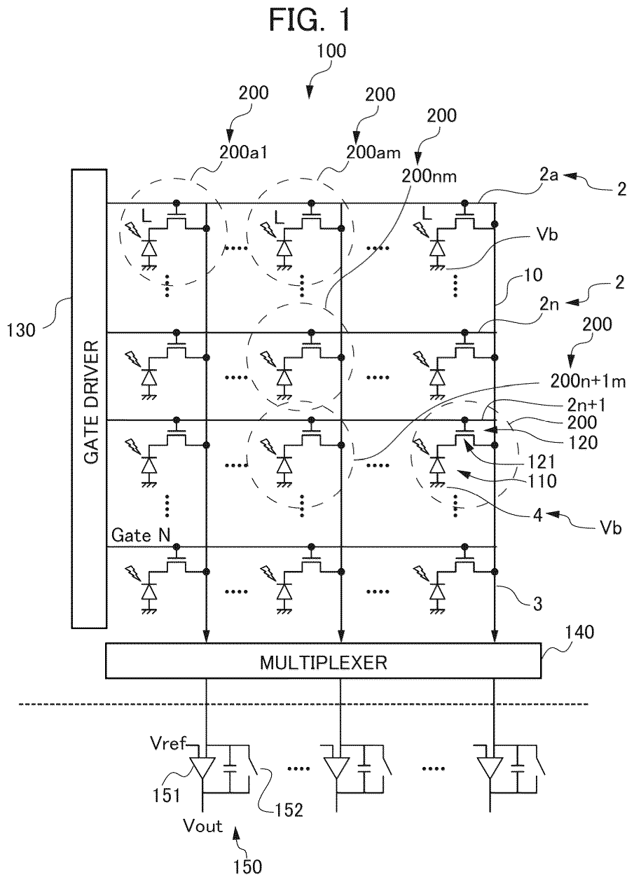

FIG. 1 is an overall circuit diagram of a two-dimensional photosensor 100 according to a first embodiment of the present invention. The two-dimensional photosensor 100 includes a photosensing portion 200, a gate driver 130, a scanning electrode 2 and a signal readout electrode 3, a multiplexer 140 and a signal processing circuit 150. The photosensing portion 200 includes a photodiode 110 and a readout circuit 120.

The photodiode 110 receives natural light L, which is light from outside, and outputs electrical current. The readout circuit 120 has a signal readout circuit thin film transistor 121. The gate driver 130 has gate signal output terminals. The gate signal output terminals connect to each of a plurality of scanning electrodes 2. The scanning electrodes 2 sequentially transmit signals from the gate driver 130 to the readout circuit 120. In the photodiode 110, one end functioning as an anode electrode is connected to a reference voltage portion 4, and the other end functioning as a cathode electrode is connected to the readout circuit 120.

The readout circuit 120 receives signals from the gate driver 130, and reads the photoelectric current of the photodiode 110. The readout circuit 120 transmits the readout photoelectric current of the photodiode 110 to the signal readout electrode 3. The signal readout electrode 3 transmits the transmitted photoelectric current to the multiplexer 140. The multiplexer 140 transmits signals from a plurality of signal readout electrodes 3 sequentially to the signal processing circuit 150. The signal processing circuit 150 processes the outputted photoelectric current of the photodiode 110 as a signal. The signal processing circuit 150 determines that light is irradiated when the photoelectric current is great, and obtains an incident light intensity based on the photoelectric current amount.

The gate driver 130 sequentially outputs voltage to a plurality of scanning electrodes 2, i.e. scanning electrode 2a, . . . , scanning electrode 2n, scanning electrode 2n+1, . . . . In other words, the scanning electrode 2 is scanned. Accompanying the scanning, the readout circuit 120 sequentially operates. The readout circuit 120 is respectively connected to the plurality of scanning electrodes 2. The readout circuit 120 connected to the scanning electrode 2a, for example, reads out the photoelectric current of the photodiode 110 when the scanning electrode 2a is scanned, and transmits to the signal processing circuit 150. Next, the readout circuit 120 connected to the scanning electrode 2n reads out the photoelectric current of the photodiode 110 when the scanning electrode 2n is scanned, and transmits to the signal processing circuit 150. By the scanning electrodes 2 being sequentially scanned, the photoelectric currents of the two-dimensionally arrayed photodiodes 110 are transmitted sequentially to the signal processing circuit 150. Then, the photoelectric current of the photodiode 110 is transmitted to the signal processing circuit 150 over the entire surface of the two-dimensional photosensor 100. The signal processing circuit 150 is digitized by the Analog to digital converter, and is connected to a central processor that is not shown. The central processor obtains the two-dimensional distribution of incident light intensity based on information obtained from the signal processing circuit 150.

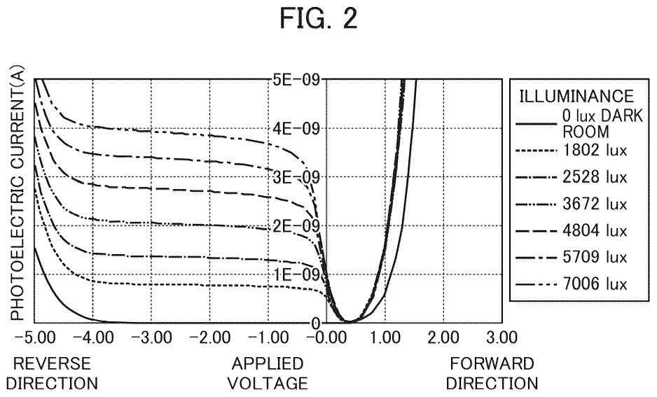

FIG. 2 is a view showing an example of the characteristics of the photodiode 110. Although the structure will be described in detail later, the photodiode 110 according to the present embodiment is a Schottky diode. The horizontal axis indicates the applied voltage to the photodiode 110. The positive direction of the horizontal axis indicates a state in which the voltage is applied to the photodiode 110 in the forward direction. The negative direction of the horizontal axis indicates a state in which the voltage is applied to the photodiode 110 in the reverse direction. The vertical direction shows the photoelectric current outputted by the photodiode 110. The units are amperes. Illuminance of natural light L irradiated onto the photodiode 110 varies from 0 lux to 7006 lux. Experimental results with the illuminance set to 0 lux indicate experimental results in a darkroom.

The data of a darkroom will be referenced. When the applied voltage is applied in the forward direction, the electric current increases. In other words, it indicates that the electric current is flowing from the photodiode 110. In the case of the applied voltage being applied in the reverse direction, i.e. case of the voltage being applied in the negative direction of the horizontal axis in FIG. 2, it is found that only a slight electric current called dark current flows till the voltage drops below −4 V.

Next, data for the case of natural light L being irradiated, and the illuminance being irradiated from 1802 lux to 7006 lux will be referenced. When the applied voltage is applied in the forward direction, the electric current increases. In other words, it indicates that electric current flows from the photodiode 110. This is similar to the data for illuminance of 0, or a darkroom. In the state applying voltage in the reverse direction, i.e. in the case of voltage being applied in the negative direction of the horizontal axis in FIG. 2, FIG. 2 is showing the flow of electric current. Then, the flowing electric current is larger with higher illuminance. For example, in the case of the applied voltage being −2 V, when the illuminance is 0 lux, a photoelectric current of substantially 0 amperes flows, which is a small dark current, when the illuminance is 1802 lux, photoelectric current of about 0.8×10⁻⁹ amperes flows, when the illuminance is 3672 lux, photoelectric current of approximately 2×10⁻⁹ amperes flows, and when the illuminance is 7006 lux, photoelectric current of approximately 3.9×10⁻⁹ amperes flows.

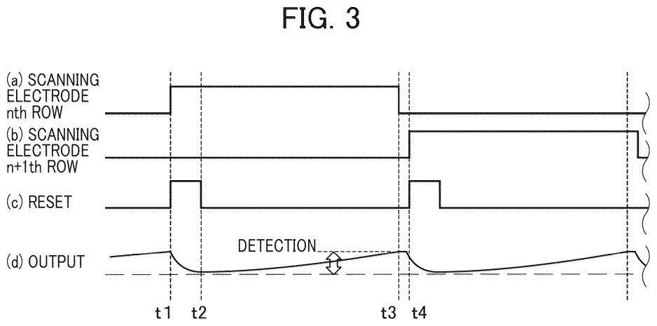

FIG. 3 is a schematic diagram showing the output signal from the gate driver 130, reset signal, and output voltage of signal processing circuit 150. The horizontal axis represents time. FIG. 3(a) represents the output voltage from the gatedriver 130 to scanning electrode 2n of the n^{th} row. FIG. 3(b) represents the output voltage from the gate driver 130 to scanning electrode 2n+1 of the n+1^{th} row. FIG. 3(c) represents a reset state of a reset switch 152 of a signal processing circuit 150 the m^{th} column shown in FIG. 1. FIG. 3(d) shows the output voltage Vout of the signal processing circuit 150, based on the photodiode 110 of the m^{th} column, n^{th} row.

When the n^{th} row scanning electrode 2 is scanned, as shown in FIG. 3(a), the ON voltage (for example, +15 V) is applied to the scanning electrode 2 of the n^{th} row at time t1. The ON voltage is applied to the scanning electrode 2 shown in FIG. 1, the gate of the signal readout circuit thin film transistor 121 opens, and the source-drain electrodes of the signal readout circuit thin film transistor 121 are conductive. In other words, the switch of the signal readout circuit thin film transistor 121 as a switch enters the ON state. At this time, as the voltage of the scanning electrode 2n+1 of the n+1^{th} row, the OFF voltage (for example, −5 V) is applied as shown in FIG. 3(b).

The signal processing circuit 150 has an operational amplifier 151 as shown in FIG. 1. The signal processing circuit 150 applies a reference voltage (referring to FIG. 1, Vref, e.g., +1.5 V) to the signal readout electrode 3 via the operational amplifier 151. At time t1, as shown in FIG. 3(c), the reset switch 152 of the signal processing circuit 150 is conductive. Then, the operational amplifier 151 is reset. As shown in FIG. 3(d), the detected voltage of the signal processing circuit 150 drops from time t1 to time t2. In other words, the voltage based on the photodiode 110 is reset. The time from time t1 to time t2 is 160 microseconds, for example. At time t2, as shown in FIG. 3(c), the reset switch 152 of the signal processing circuit 150 turns OFF. At this time, the reference voltage is applied to the photodiode 110 as voltage of reverse bias. To the scanning electrode 2 of the n^{th} row, the ON voltage is applied until time t3, as shown in FIG. 3(a). Then, the photoelectric current flows in the photodiode 110 due to natural light L, and the voltage of the signal readout electrode 3 is about to drop. According to the operation of the operational amplifier 151 of the signal processing circuit 150, the output voltage (Vout) of the signal processing circuit 150 gradually increases from time t2 to time t3, as shown in FIG. 3(d). At time t3, the OFF voltage is applied to the scanning electrode 2 of the n^{th} row, as shown in FIG. 3(a). The output voltage (Vout) of the signal processing circuit 150 reaches a maximum at time t3, as shown in FIG. 3(d). Through the signal processing circuit 150, the voltage at time t3 is detected as a voltage representing the intensity of light incident on the photodiode 110.

At time t4, the ON voltage is applied to the scanning electrode 2 of the n+1^{th} row. Hereinafter, the intensity of light incident on the photodiode 110 is detected similarly for the n+1^{th} row and higher. The above scanning is performed from the first row to the final row, and the scanning returns to the first row after the final row. Based on the photoelectric current of the photodiode 110, the intensity of the incident light is detected from the first column of the first row to the final column, and further till the final column of the final row. In other words, the incident light intensity is detected in a two-dimensional plane.

Operation of the two-dimensional photosensor 100 has been described above as the operation of an electronic circuit. Hereinafter, the structure of the two-dimensional photosensor 100 according to the present embodiment will be described.

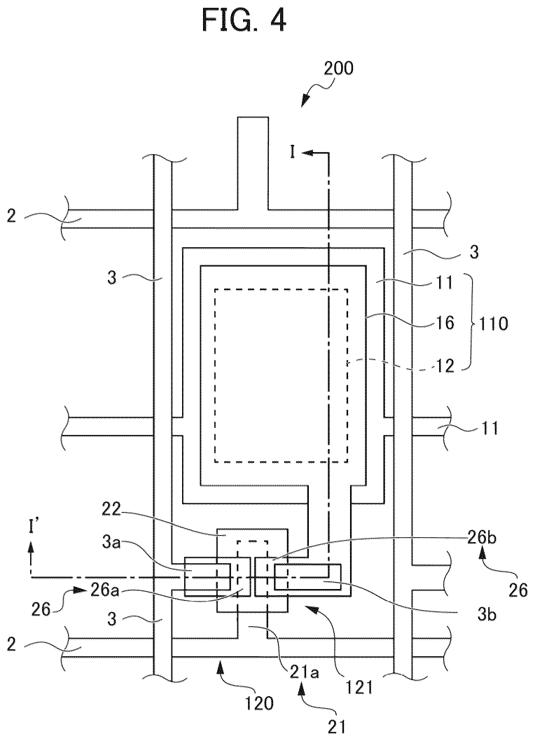

FIG. 4 is a plan view of a photosensing portion 200. The photosensing portion 200 includes the photodiode 110 and the readout circuit 120. The readout circuit 120 includes a signal readout circuit thin film transistor 121. The photodiode 110 includes a first metal electrode 11, a first semiconductor layer 12 and a first transparent electrode 16. The signal readout circuit thin film transistor 121 includes a first gate electrode 21a, a third insulating layer 24 not shown in FIG. 4, a second semiconductor layer 22, a transparent source electrode 26a and a transparent drain electrode 26b.

The first metal electrode 11 extends linearly in the left/right direction of the two-dimensional photosensor 100. The first metal electrode 11 is connected to the reference voltage portion 4, which is shown in FIG. 1, but not shown in FIG. 4. The first metal electrode 11 extends and spreads in a rectangle form in the up/down direction of the photosensing portion 200. A first semiconductor layer 12 is formed in an island shape on the first metal electrode 11. So as to cover the first semiconductor layer 12, a first ohmic contact layer 13, which is not shown in FIG. 4, is formed in an island shape. The first insulating layer 14, which is not shown in FIG. 4, is arranged so as to cover part of the glass substrate 1 and the first ohmic contact layer 13. The first transparent electrode 16 is arranged in a planar manner to contact the first ohmic contact layer 13.

The scanning electrode 2 extends in the left/right direction of the two-dimensional photosensor 100, and in the left/right direction of the photosensing portion 200 as shown in FIG. 1, for example. The scanning electrode 2 has an extension portion in the two-dimensional plane of the photosensing portion 200. The signal readout circuit thin film transistor 121 includes an extension portion of the above-mentioned scanning electrode 2 as a first gate electrode 21a. The signal readout circuit thin film transistor 121 includes a third insulating layer 24 of a planar shape on the first gate electrode 21a. The signal readout circuit thin film transistor 121 includes a second semiconductor layer 22 on the third insulating layer 24. The second semiconductor layer 22 is an island shape. The signal readout circuit thin film transistor 121 may have an ohmic contact layer on the second semiconductor layer 22. The signal readout circuit thin film transistor 121 includes the transparent source electrode 26a and the transparent drain electrode 26b. The signal readout electrode 3 includes a branch-shaped extension portion. The extension portion of the signal readout electrode 3 conducts with the transparent source electrode 26a of the signal readout circuit thin film transistor 121, and constitutes the metal source electrode 3a. The same layer as the signal readout electrode 3 constitutes the metal drain electrode 3b of a rectangular island shape. The metal drain electrode 3b conducts with the transparent drain electrode 26b. The transparent drain electrode 26b electrically conducts with the first transparent electrode 16 possessed by the photodiode 110. When a predetermined voltage, for example, 15 V, is applied to the first gate electrode 21a, the transparent source electrode 26a and the transparent drain electrode 26b are conductive. The signal readout circuit thin film transistor 121 functions as a switch.

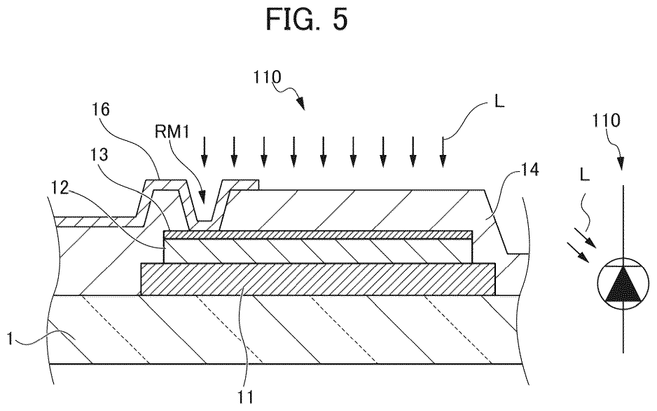

FIG. 5 is a cross-sectional view of the photodiode 110 along the line I-I′ in FIG. 4. The photodiode 110 is arranged on the glass substate 1. The glass substrate 1 may be a film substrate. The photodiode 110 includes a laminate of the first metal electrode 11, the first semiconductor layer 12, the first ohmic contact layer 13, the first insulating layer 14 and the first transparent electrode 16. The constituent layers omitted from illustration in FIG. 4 are shown in FIG. 5.

The glass substrate 1 is a non-alkali glass, for example, borosilicate glass. The glass substrate 1 has a thickness of 0.5 to 0.7 mm, for example. The first metal electrode 11 is arranged on the glass substrate 1. The first metal electrode 11, for example, has a substantially oblong shape as shown in FIG. 4, for example. The first metal electrode 11 is an alloy of molybdenum and tantalum, for example. Additionally, a low-resistance metal such as aluminum (Al) or copper (Cu) can be exemplified. The first metal electrode 11, for example, has a thickness of 200 nm. The first semiconductor layer 12 is arranged on the first metal electrode 11. The first semiconductor layer 12 has a substantially oblong shape, as shown in FIG. 4, for example. The first semiconductor layer 12 is an amorphous silicon layer, for example. The first semiconductor layer 12 has a thickness of 200 nm, for example. The first ohmic contact layer 13 is arranged on the first semiconductor layer 12. The first ohmic contact layer 13 is an amorphous silicon layer to which donor atoms were added as impurities, for example. Hereinafter, the above-mentioned amorphous silicon layer doped with donor atoms is called n+amorphous silicon layer. The n− amorphous silicon layer has a thickness of 50 nm, for example. The first insulating layer 14 is arranged so as to cover the first metal electrode 11, the first semiconductor layer 12, and the first ohmic contact layer 13. The first insulating layer 14, for example, is a silicon nitride (SiN) film. The first insulating layer 14 has a thickness of 400 nm, for example. A part of the first insulating layer 14 is not arranged on top of the first ohmic contact layer 13 in an insulating layer removal portion RM1. The first transparent electrode 16 is arranged on the first insulating layer 14. In particular, the first transparent electrode 16 is arranged so as to cover over the first ohmic contact layer 13 on which the first insulating layer 14 is not arranged. The first transparent electrode 16 is a film of an oxide of indium and titanium oxide (ITO), for example. As the transparent electrode, in addition to ITO, an oxide of indium and zinc alloy (IZO), an oxide of aluminum and zinc (AlZn oxide) or the like can be exemplified. The first transparent electrode 16 has a thickness of 100 nm, for example. The first transparent electrode 16 and the first ohmic contact layer 13 contact to be in electrical connection.

A Schottky barrier section S is formed between the first metal electrode 11 and the first semiconductor layer 12. On the other hand, since the first ohmic contact layer 13 exists, the first transparent electrode 16, the first ohmic contact layer 13 and the first semiconductor layer 12 are in ohmic contact, and a Schottky barrier is not generated. The first metal electrode 11, the first semiconductor layer 12, the first ohmic contact layer 13 and the first transparent electrode 16 constitute the Schottky diode. A schematic diagram of the diode circuit is depicted on the right of FIG. 5. As represented in the present schematic diagram, the Schottky diode with the direction from the first metal electrode 11 to the first transparent electrode 16 defined as the forward direction is realized.

The Schottky barrier section S is produced at the interface between the first metal electrode 11 and the first semiconductor layer 12. For this reason, the thickness of the first semiconductor layer 12 can be made thinner. However, the electric field of the Schottky barrier portion concentrates when too thin, and leakage current will increase. On the other hand, when the amorphous silicon layer is thick, the resistance increases, and the photoelectric current decreases. In the present embodiment, for example, an amorphous silicon layer of 200 nm thickness is arranged. The thickness of the amorphous silicon layer is preferably 50 nm or more and 500 nm or less.

Rather than a Schottky diode, for example, in the case of establishing a PIN-type diode, the amorphous silicon layer is thick on the order of 1-2 microns, for example. Then, light cannot pass through the amorphous silicon layer. The first semiconductor layer 12 constituted by amorphous silicon according to the present invention is thin at 200 nm, for example, and the natural light L penetrates. The natural light L reaches the Schottky barrier section S at the entire surface of the first semiconductor layer 12 constituted by amorphous silicon. The photosensing portion 200 having a wide light receiving area can be realized with a simple configuration.

In the present embodiment, the natural light L is incident from the upward direction of the paper plane of FIG. 5, from the side on which the first transparent electrode 16 is arranged. The first transparent electrode 16 and the first insulating layer 14 have high light permeability. The natural light L passes through the first transparent electrode 16 and the first insulating layer 14. The natural light L is incident on the interface between the first semiconductor layer 12 and the first metal electrode 11, at which the Schottky barrier is realized. The natural light L is absorbed by the first semiconductor layer 12. The natural light L is incident to the first semiconductor layer 12 from the side of the first transparent electrode 16. Then, the charge carrier pairs of the Schottky barrier are released. The free charge carriers give rise to photoelectric current.

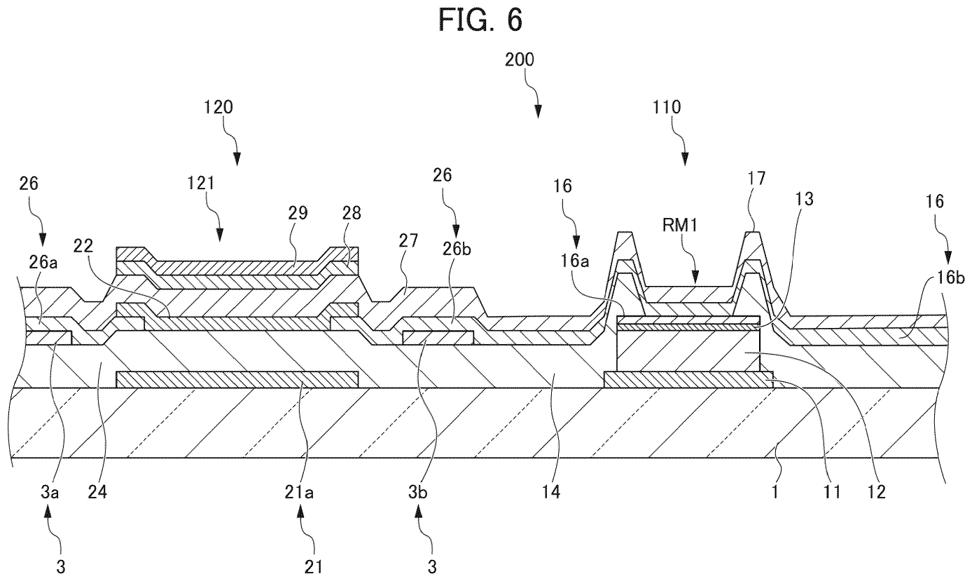

FIG. 6 is a cross-sectional view of the photosensing portion 200 corresponding to the line I-I′ in FIG. 4. The photosensing portion 200 includes a photodiode 110 and a readout circuit 120.

The photodiode 110 shown in FIG. 6 serves as a modified example of the photodiode 110 shown in FIG. 5, and the first transparent electrode 16 is formed in two layers. The two layers of the first transparent electrode 16 are distinguished noting as a first transparent electrode 16a which is a lower layer, and a first transparent electrode 16b which is an upper layer.

The photodiode 110 includes the first metal electrode 11, the first semiconductor layer 12, the first ohmic contact layer 13, the first transparent electrode 16, the first insulating layer 14, and the second insulating layer 17. It will be compared with the photodiode 110 shown in FIG. 5. A configuration in which the first metal electrode 11, the first semiconductor layer 12 and the first ohmic contact layer 13 are arranged in this order on the glass substrate 1 is shared between the photodiode 110 shown in FIG. 6 and the photodiode 110 shown in FIG. 5. In the photodiode 110 shown in FIG. 6, the first transparent electrode 16a which is the lower layer is arranged on the entire surface of the first ohmic contact layer 13. FIG. 5 and FIG. 6 share the point of the first insulating layer 14 being formed on the first ohmic contact layer 13, and the insulating layer removal portion RM1 being provided as a region partially without this layer. In the photodiode 110 shown in FIG. 6, the first transparent electrode 16b which is the upper layer is provided on the first insulating layer 14. The first transparent electrode 16b which is the upper layer is arranged so as to cover the insulating layer removal portion RM1. The point of this first transparent electrode 16b which is the upper layer being arranged so as to cover the insulating layer removal portion RM1 is common with the point of the first transparent electrode 16 being arranged so as to cover the insulating layer removal portion RM1 of the photodiode 110 shown in FIG. 5. Although the manufacturing method will be described later, in the case of the configuration in FIG. 5 for the patterning of the first insulating layer 14, there is a possibility of the first ohmic contact layer 13 also being patterned. In the case of the configuration of FIG. 6, since the first transparent electrode 16a which is the lower layer plays the role of a stopper, there is a low possibility of the first ohmic contact layer 13 being patterned. The configuration of FIG. 5 is simple, and shows a basic configuration. The configuration of FIG. 6 has higher reliability. Furthermore, the second insulating layer 17 is arranged on the first transparent electrode 16b, which is the upper layer.

The readout circuit 120 will be described by referencing FIGS. 4 and 6. The readout circuit 120 includes a signal readout circuit thin film transistor 121 and a signal readout electrode 3. The signal readout circuit thin film transistor 121 includes a second metal electrode 21, a third insulating layer 24, a second semiconductor layer 22, a second transparent electrode 26, a fourth insulating layer 27, a third metal electrode 28 and a third transparent electrode 29.

The second metal electrode 21 is arranged on the glass substrate 1. The second metal electrode 21 and the first metal electrode 11 are formed simultaneously as described later, and configured by the same layer. Herein, same layer includes layers formed simultaneously, layers of substantially the same thickness, and layers of the same material. The same applies below. The present process is a metal electrode film forming step of simultaneously forming the first metal electrode 11 and the second metal electrode 21. The second metal electrode 21, for example, is an alloy of molybdenum and tantalum. The second metal electrode 21, for example, has a thickness of 200 nm. The second metal electrode 21 also constitutes the scanning electrode 2 shown in FIG. 4. As shown in FIG. 4, part of the scanning electrode 2 extends in a branched manner, and configures part of the signal readout circuit thin film transistor 121. This extending portion constitutes a first gate electrode 21a of the signal readout circuit thin film transistor 121.

The third insulating layer 24 is arranged so as to cover the second metal electrode 21 on the second metal electrode 21. The third insulating layer 24, for example, is a silicon nitride (SiN) film. The third insulating layer 24, for example, has a thickness of 400 nm. The third insulating layer 24 and the first insulating layer 14 are formed simultaneously as described later, and are configured by the same layer. The present process is an insulating layer film forming step of simultaneously forming the first insulating layer 14 and the third insulating layer 24.

The signal readout electrode 3 is provided on the third insulating layer 24. The signal readout electrode 3 is a metal electrode, for example, of chromium (Cr), aluminum (Al), titanium (Ti) or the like. As shown in FIG. 4, the signal readout electrode 3 extends in the up/down direction of the two-dimensional photosensor 100. Part of the signal readout electrode 3 extends in a branched manner in a horizontal direction, e.g., the right direction in FIG. 4. The extending portion of the signal readout electrode 3 constitutes a part of the readout circuit 120, as shown at the left end of FIG. 6. The extending portion of the signal readout electrode 3 superimpose and electrically connect with the second transparent electrode 26 described later, and constitutes a metal source electrode 3a and a metal drain electrode 3b. The metal source electrode 3a and the metal drain electrode 3b have functions of lowering the resistance of the transparent source electrode 26a and the transparent drain electrode 26b of the second transparent electrode 26; whereas, only the second transparent electrode 26 has high resistance.

The second transparent electrode 26 is arranged on the third insulating layer 24, and on the extension part of the scanning electrode 2, i.e. first gate electrode 21a, so as to partially overlap. The second transparent electrode 26, for example, is an ITO film. The second transparent electrode 26, for example, has a thickness of 100 nm. The second transparent electrode 26 constitutes the transparent source electrode 26a and the transparent drain electrode 26b of the signal readout circuit thin film transistor 121. The transparent drain electrode 26b which is part of the second transparent electrode 26 is electrically connected with the first transparent electrode 16. Alternatively, as described later, the second transparent electrode 26 and the first transparent electrode 16 are formed simultaneously, and are constituted by the same layer. The present process is a transparent electrode film forming step of simultaneously forming the first transparent electrode 16 and the second transparent electrode 26.

The second semiconductor layer 22 is arranged in an island shape as shown in FIG. 4. The second semiconductor layer 22 is arranged over the third insulating layer 24 and overlapping the second transparent electrode 26, as shown in FIG. 6. The second semiconductor layer 22, for example, is constituted by a transparent oxide semiconductor (hereinafter IGZO) configured from indium (In), gallium (Ga), zinc (Zn) and oxygen (O).

The fourth insulating layer 27 is arranged over the second semiconductor layer 22 and the second transparent electrode 26 so as to overlap these. The fourth insulating layer 27 and the second insulating layer 17 may be formed simultaneously as described layer, and are configured by the same layer. The present process is an insulating layer film forming step of simultaneously forming the second insulating layer 17 and the fourth insulating layer 27.

The third metal electrode 28 is arranged at a position overlapping the second metal electrode 21 viewed from the perpendicular direction to the glass substate 1, i.e. from above of the paper plane. The second metal electrode 21 functions as a first gate electrode 21a, and the third metal electrode 28 functions as a second gate electrode 21b. The first gate electrode 21a and the second gate electrode 21b function as gate electrodes of the signal readout circuit thin film transistor 121, and govern ON/OFF as a switch of the signal readout circuit thin film transistor 121. The third transparent electrode 29 is arranged at a position overlapping with the third metal electrode 28, viewed from a direction perpendicular to the glass substrate 1, i.e. above the paper plane.

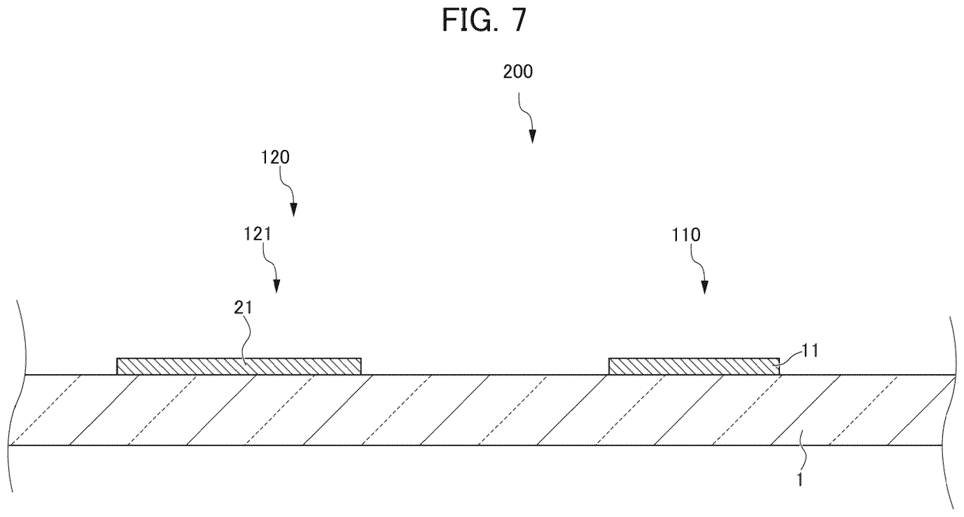

The manufacturing method of the photosensing portion 200 shown in FIG. 6 will be described by referencing FIGS. 7 to 14. FIGS. 7 to 14 are cross-sectional views of each manufacturing process of the photosensing portion 200. The photosensing portion 200 includes the photodiode 110 and the readout circuit 120.

Although the details are described later In the first embodiment, after forming the photodiode 110, the signal readout circuit thin film transistor 121 including IGZO as the semiconductor layer is formed. It is preferable to form in this sequence. In the case of manufacturing from IGZO, hydrogen is added to the IGZO from amorphous silicon during preparation of the photodiode 110, and there is a possibility of being difficult to obtain favorable characteristics in the thin film transistor of IGZO.

As shown in FIG. 7, the first metal electrode 11 and the second metal electrode 21 are simultaneously formed on the glass substrate 1. The present process is a metal electrode film forming step of simultaneously forming the first metal electrode 11 and the second metal electrode 21. This formation step is one of the steps whereby a layer constituting the photodiode 110 and the signal readout circuit thin film transistor 121 are simultaneously deposited or formed. For example, a metal thin film of chrome, aluminum, titanium or the like is formed by sputtering. The metal thin film, for example, has a thickness of about 200 nm. A photoresist is coated on this thin film. The pattern of the metal thin film is formed by photolithography. For example, the metal thin film of a portion not covered by resist is etched by a chlorine-based dry etching method. The first metal electrode 11 has, for example, the pattern shown in the plan view of FIG. 4. The second metal electrode 21 includes, for example, the pattern shown in the plan view of FIG. 4.

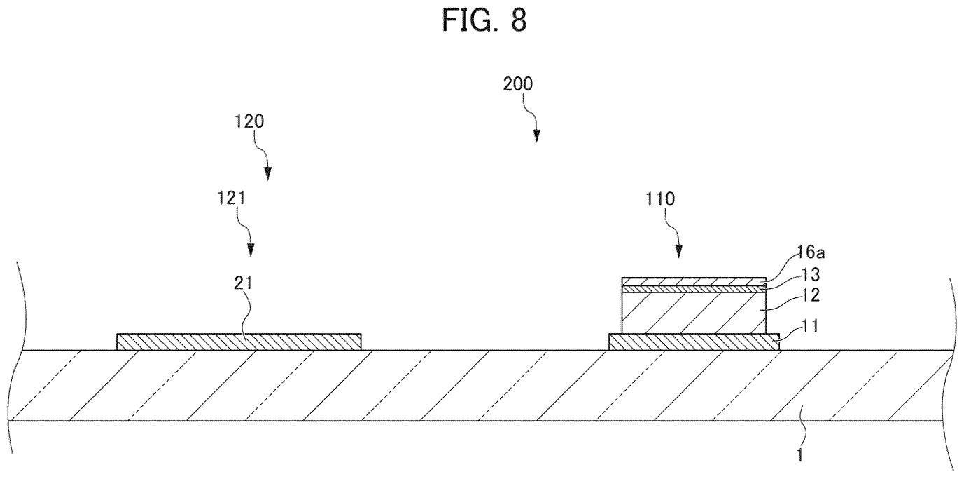

Next, as shown in FIG. 8, the first semiconductor layer 12, the first ohmic contact layer 13, the first transparent electrode 16a which is the lower layer are continuously laminated to constitute a laminate body. The first semiconductor layer 12, for example, is an amorphous silicon (a-Si) layer. The first ohmic contact layer 13, for example, is an n+ amorphous silicon (n+ a-Si) layer. The first transparent electrode 16a which is the lower layer, for example, is ITO. Through the dry etching processing step, the laminate body is patterned in an island shape. The island-shaped pattern of the laminate body overlaps the island-shaped pattern of the first metal electrode 11, and has a smaller area than the island-shaped pattern of the first metal electrode 11, as shown in FIG. 4, for example.

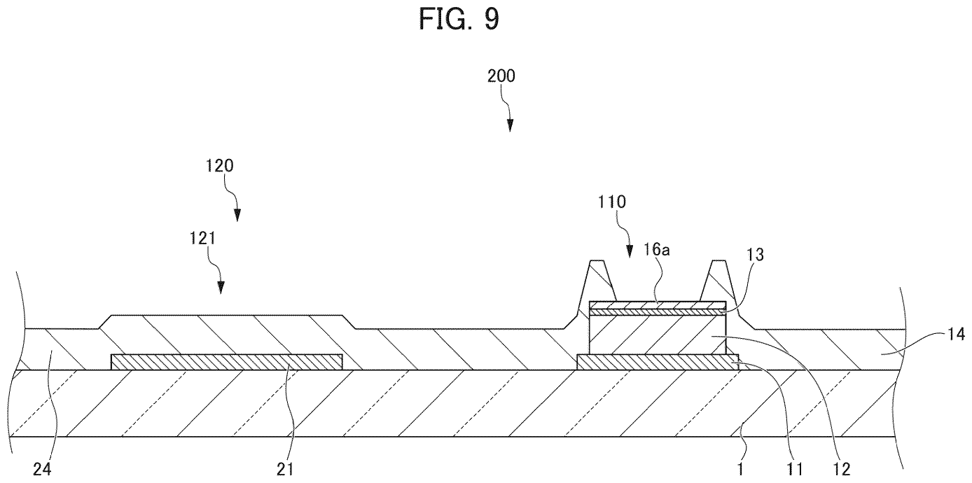

Next, as shown in FIG. 9, the first insulating layer 14 and the third insulating layer 24 are formed simultaneously. The first insulating layer 14 and the third insulating layer 24 are configured by the same layer. The present process is an insulating layer film forming step of simultaneously forming the insulating layer of the photodiode 110 and the insulating layer of the signal readout circuit thin film transistor 121. The first insulating layer 14 and the third insulating layer 24, for example, are SiN films. The SiN films, for example, are formed by a plasma CVD method or the like. The SiN films, for example, are patterned by SF-based dry etching. In particular, a part of the first transparent electrode 16a which is the lower layer is patterned so as to be exposed. Herein, the first transparent electrode 16a which is the lower layer functions as an etching stopper. Since the etching is stopped at the first transparent electrode 16a, the n+ amorphous silicon is not etched away. A configuration without the first transparent electrode 16a shown in FIG. 5 is also effective. In a case without the first transparent electrode 16a which is the lower layer, precise management of the etching finish point in time of the SF₆-based dry etching becomes necessary. Since there is no etching stopper, there is a possibility of the n+ amorphous silicon being etched away. It is necessary to precisely manage the end point of etching so that the n+ amorphous silicon will not be etched away.

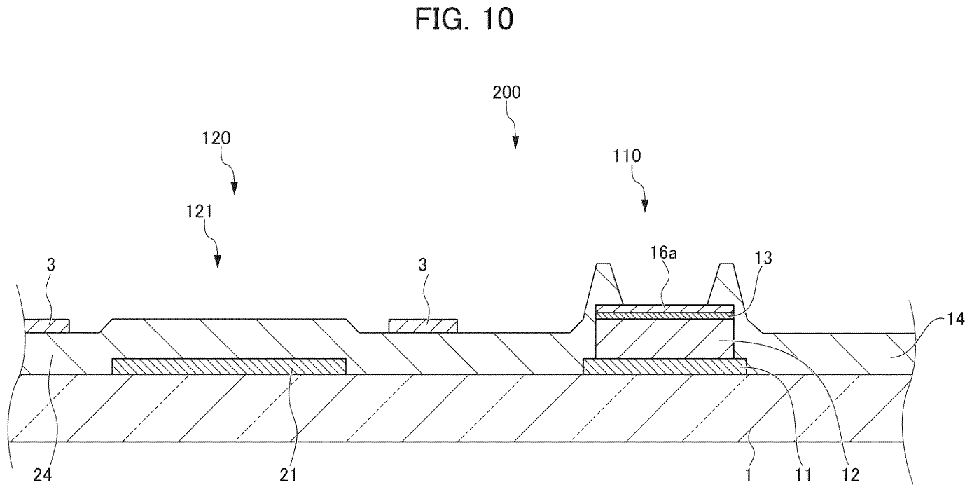

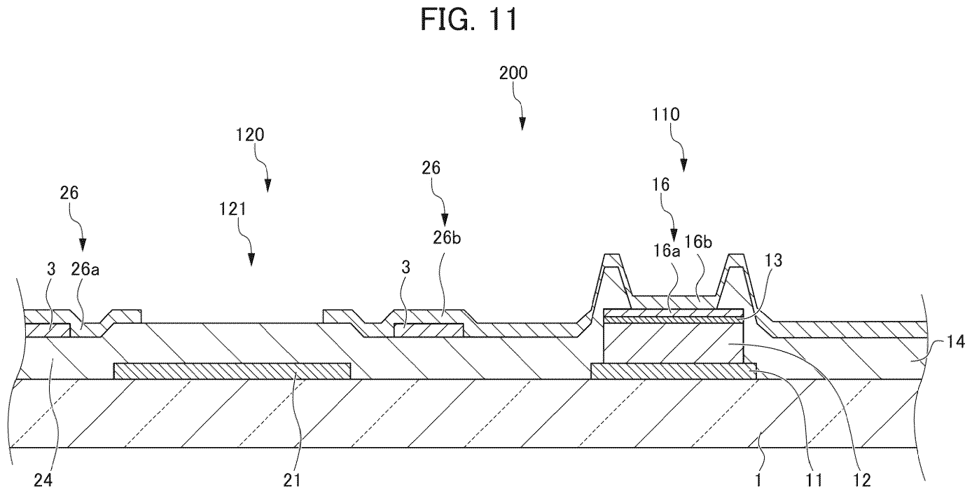

Next, as shown in FIG. 10, the signal readout electrode 3 is formed. The signal readout electrode 3, for example, is a metal thin film of chromium (Cr), aluminum (Al), titanium (Ti) or the like. After the metal thin film is formed, it is patterned by chlorine-based dry etching. Next, as shown in FIG. 11, simultaneously with the first transparent electrode 16b which is the upper layer being formed, the second transparent electrode 26 is formed. The first transparent electrode 16b which is the upper layer and the second transparent electrode 26 are formed by the same layer. The present process is a transparent electrode film forming step of simultaneously forming the first transparent electrode 16b which is the upper layer and the second transparent electrode 26. The second transparent electrode 26 configures a transparent source electrode 26a and a transparent drain electrode 26b of the signal readout circuit thin film transistor 121. The transparent drain electrode 26b electrically connects continuous with the first transparent electrode 16b which is the upper layer of the photodiode 110.

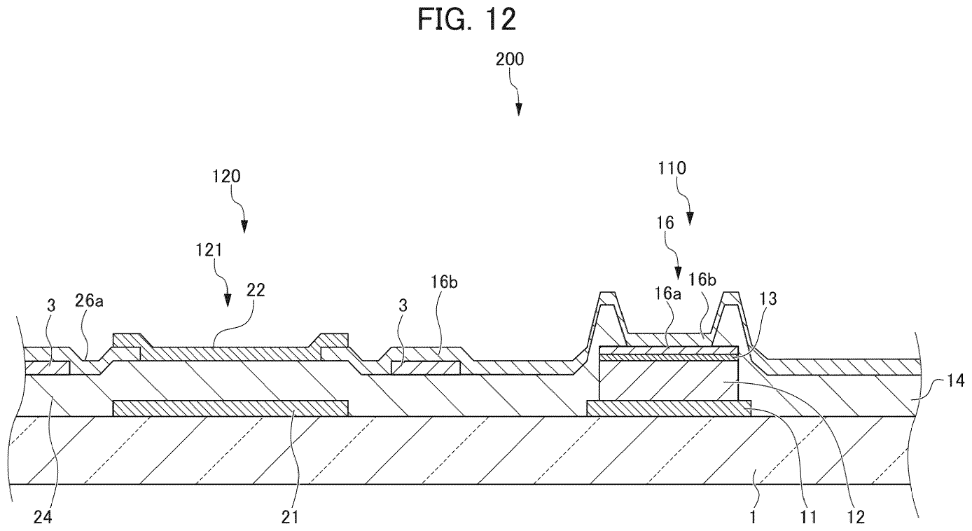

Next, as shown in FIG. 12, the second semiconductor layer 22 is formed. The second semiconductor layer 22, for example, is configured by the IGZO layer. The IGZO layer, for example, is formed by a sputtering method using an oxide semiconductor target including In, Ga and Zn. The IGZO film is etched using an organic acid such as citric acid or oxalic acid as an etchant, for example.

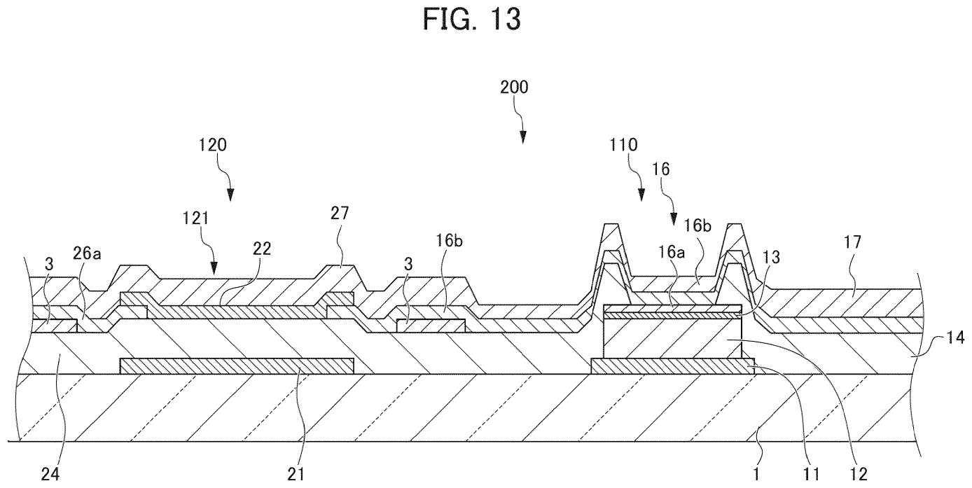

Next, as shown in FIG. 13, the second insulating layer 17 and the fourth insulating layer 27 are formed simultaneously. The second insulating layer 17 and the fourth insulating layer 27 are configured by the same layer. The present process is an insulating layer film forming step of simultaneously forming the second insulating layer 17 and the fourth insulating layer 27. The second insulating layer 17 and the fourth insulating layer 27, for example, are silicon oxide (SiO₂), and are formed by a plasma CVD method, for example.

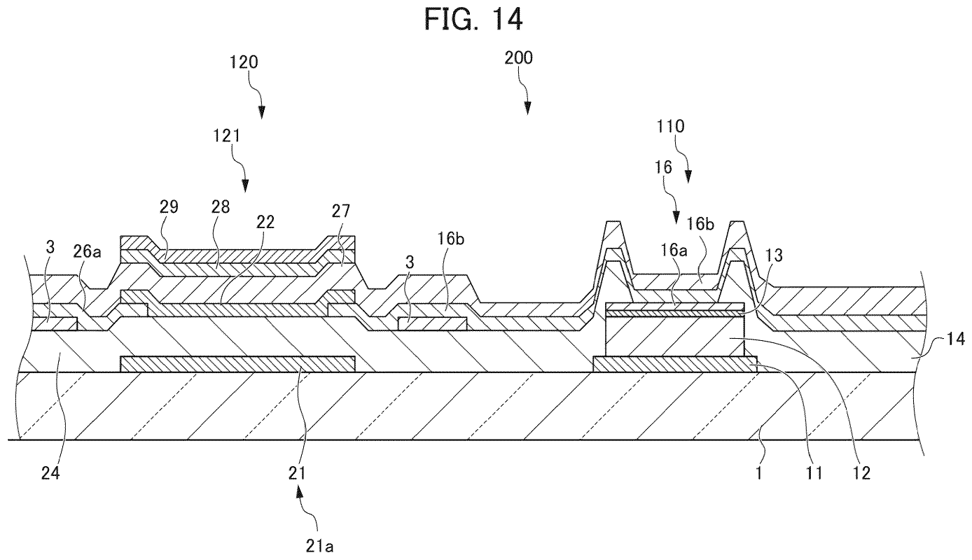

Next, as shown in FIG. 14, the third metal electrode 28 and the third transparent electrode 29 are laminated and patterned. The third metal electrode 28, for example, is a metal electrode of chromium (Cr), aluminum (Al), titanium (Ti), or the like. The third metal electrode 28 functions as the second gate electrode 21b in the signal readout circuit thin film transistor 121. The present configuration has been known as a double gate configuration from the prior art. The third metal electrode 28 assists in the second metal electrode 21 functioning as the first gate electrode 21a. The third transparent electrode 29 covers the third metal electrode 28, and has an action of preventing deterioration of the third metal electrode 28.

### First Modified Example

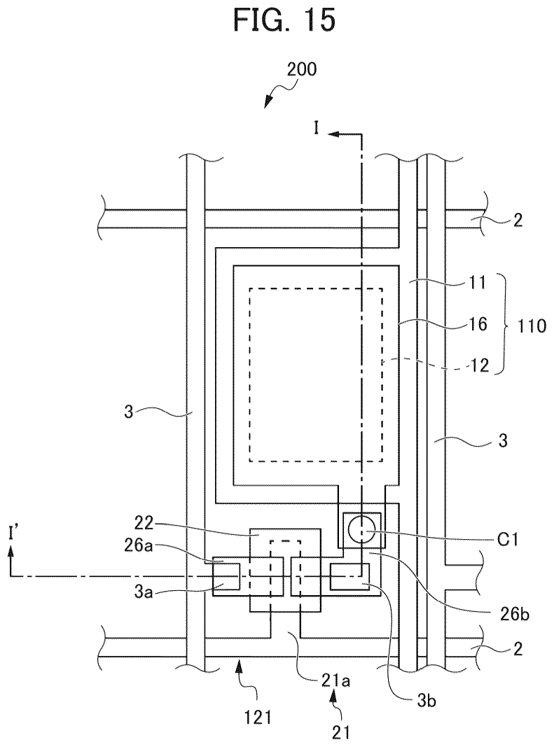

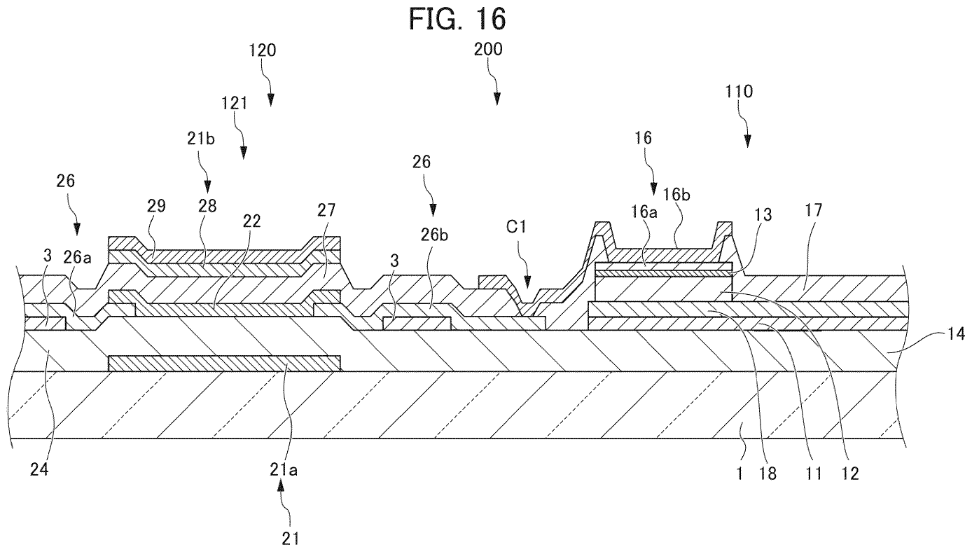

In the above described embodiment, in the photodiode 110 and the signal readout circuit thin film transistor 121 as shown in FIG. 6, the first semiconductor layer 12 is configured with amorphous silicon, and the second semiconductor layer 22 is configured with IGZO, and thus differ from each other. In Modified Example 1, the first semiconductor layer 12 and the second semiconductor layer 22 are different. However, in Modified Example 1, the layers formed by constituent elements possessed by the photodiode 110 differ. Modified Example 1 will be described by referencing FIGS. 15 and 16. FIG. 15 is a plan view of the photosensing portion 200 according to Modified Example 1. FIG. 16 is a cross-sectional view of the photosensing portion 200 according to Modified Example 1.

In Modified Example 1, as shown in FIG. 16, the first metal electrode 11 is configured by the same layer as the signal readout electrode 3. The present process is a metal electrode film forming step of simultaneously forming the first metal electrode 11 and the signal readout electrode 3. FIG. 15 will be compared with FIG. 4. In FIG. 4, the first metal electrode 11 determining the reference voltage Vb of the photodiode 110 runs in the left/right direction of the drawing, parallel to the scanning electrode 2. This is because the first metal electrode 11 is configured by the same layer as the scanning electrode 2. On the other hand, in FIG. 15 showing Modified Example 1, the first metal electrode 11 is arranged in parallel with the signal readout electrode 3, in the up/down direction of the drawing. The first metal electrode 11 and the signal readout electrode 3 are not intended to intersect, and the first metal electrode 11 is arranged in parallel to the signal readout electrode 3. This is because the first metal electrode 11 is configured by the same layer as the signal readout electrode 3. The reference voltage Vb, e.g., −1 V, is applied to the first metal electrode 11.

Referencing FIG. 16, the structure of the photodiode 110 in Modified Example 1 and the manufacturing method thereof will be described.

The second metal electrode 21 is arranged on the glass substrate 1. The second metal electrode 21 extends in a branched manner from the scanning electrode 2 as shown in FIG. 15, and functions as a first gate electrode 21a of the signal readout circuit thin film transistor 121. The second metal electrode 21, for example, is configured by a laminate body of titanium, aluminum and titanium, or by aluminum, molybdenum, copper or the like.

Next, the first insulating layer 14 and the third insulating layer 24 are formed simultaneously. The present process is an insulating layer film forming step in which the first insulating layer 14 and the third insulating layer 24 are simultaneously formed. The third insulating layer 24, for example, is configured by silicon nitride (SiN). The third insulating layer 24, for example, has a thickness of 400 nm.

Next, simultaneously with the first metal electrode 11 being formed on the first insulating layer 14 (same layer as third insulating layer 24), the signal readout electrode 3 of the signal readout circuit thin film transistor 121 is formed on the third insulating layer 24. The first metal electrode 11 and the signal readout electrode 3 are configured by the same layer. The present process is a metal electrode film forming step of simultaneously forming the first metal electrode 11 and the signal readout electrode 3. The first metal electrode 11 extends linearly up and down as shown in FIG. 15, and includes a rectangular extension portion. The signal readout electrode 3 includes the extension portion as shown in FIG. 15. The extension portion does not contact with the second semiconductor layer 22 described later, and is arranged in proximity to a channel portion of the second semiconductor layer 22. An alloy of molybdenum and tantalum (MoTa), for example, is ideal for the first metal electrode 11 and the signal readout electrode 3.

As shown in FIG. 16, the fourth transparent electrode 18 is formed over the first metal electrode 11 so as to cover the first metal electrode 11. The second transparent electrode 26 is formed simultaneously. The present process is a transparent electrode film forming step in which the fourth transparent electrode 18 and the second transparent electrode 26 are formed simultaneously. The fourth transparent electrode 18 and the second transparent electrode 26, for example, are ITO. The fourth transparent electrode 18 and the second transparent electrode 26, along with the first metal electrode 11 and the signal readout electrode 3 are patterned by a wet process of hydrochloric acid, oxalic acid or the like, or a dry process. The second transparent electrode 26 is patterned to configure the transparent source electrode 26a and the transparent drain electrode 26b.

Next, the first semiconductor layer 12, the first ohmic contact layer 13 and the first transparent electrode 16a which is the lower layer are sequentially formed, and then batch patterned in an island shape. The first semiconductor layer 12 is amorphous silicon, the first ohmic contact layer 13 is an n+ amorphous silicon layer, and the first transparent electrode 16a which is the lower layer is ITO. In the patterning, a chlorine-based dry etching method can be used. During batch patterning in an island shape, the first transparent electrode 16a which is the lower layer functions as a so-called etching stopper which prevents the first ohmic contact layer 13 from being etched.

Next, the second semiconductor layer 22 is formed. The second semiconductor layer 22, for example, includes IGZO. The IGZO layer, for example, is formed with a sputtering method using an oxide semiconductor target including In, Ga and Zn. The IGZO film is etched using an organic acid such as citric acid and oxalic acid as an etchant, for example.

The second insulating layer 17 is formed so as to cover the first transparent electrode 16a which is the lower layer. In an upper part of the first transparent electrode 16a which is the lower layer, a portion of the second insulating layer 17 is removed. Herein, the first transparent electrode 16a which is the lower layer is configured so that etching of the second insulating layer 17 does not erode the first ohmic contact layer 13. The fourth insulating layer 27 is formed simultaneously with the second insulating layer 17. The fourth insulating layer 27 and the second insulating layer 17 are configured by the same layer. The present process is an insulating layer film forming step of simultaneously forming the second insulating layer 17 and the fourth insulating layer 27. The second insulating layer 17 and the fourth insulating layer 27, for example, are silicon oxides (SiOx). A part of the fourth insulating layer 27 is removed in a portion constituting the transparent drain electrode 26b. The portion in which the fourth insulating layer 27 was removed functions as a first contact hole portion C1.

The third metal electrode 28 is formed and patterned. The third metal electrode 28, for example, is an alloy of molybdenum and tantalum (MoTa). The third metal electrode 28 is patterned so as to overlap in a plan view with the first gate electrode 21a, and functions as the second gate electrode 21b.

The first transparent electrode 16b which is the upper layer is formed so as to cover the first transparent electrode 16a which is the lower layer and the first contact hole portion C1, and is patterned. The first transparent electrode 16b which is the upper layer is formed simultaneously with the third transparent electrode 29. The present process is a transparent electrode film forming step of simultaneously forming the first transparent electrode 16b which is the upper layer and the third transparent electrode 29. The first transparent electrode 16b which is the upper layer conducts with the transparent drain electrode 26b through the first contact hole portion C1.

The photoelectric current formed by the photodiode 110 reaches the transparent drain electrode 26b from the first transparent electrode 16 through the first contact hole portion C1, and with the first gate electrode 21a and the second gate electrode 21b entering the ON state, arrives at the transparent source electrode 26a. The signal reaches the signal processing circuit 150 shown in FIG. 1 from the transparent source electrode 26a through the signal readout electrode 3.

Although illustration is omitted in FIG. 16, the second gate electrode 21b is electrically connected with the first gate electrode 21a. The second gate electrode 21b cooperates with the first gate electrode 21a to reinforce the switching function of the signal readout circuit thin film transistor 121. Furthermore, it may be a configuration in which only the second gate electrode 21b is formed, and the first gate electrode 21a does not exist. This configuration is a configuration of only the top gate. In the present configuration, IGZO is suited as the second semiconductor layer 22. This is because IGZO has high mobility.

### Second Embodiment

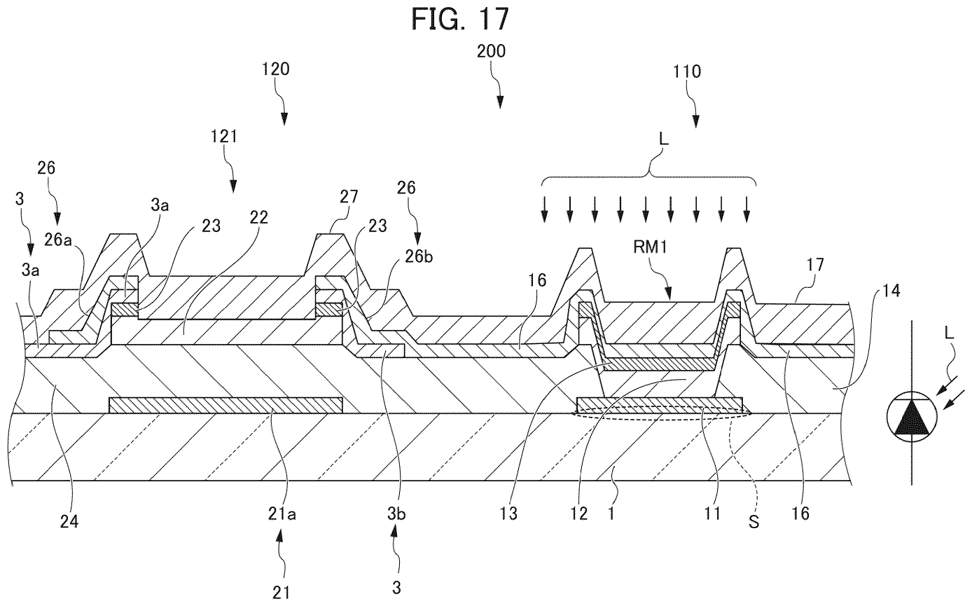

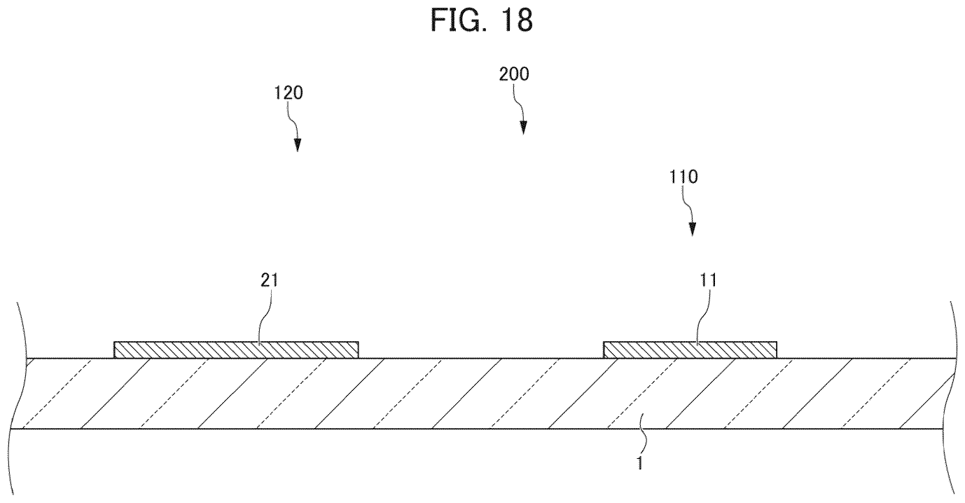

In the first embodiment, the first semiconductor layer 12 of the photodiode 110 and the second semiconductor layer 22 of the signal readout circuit thin film transistor 121 had different semiconductor layers. In contrast, in the second embodiment, the first semiconductor layer of the photodiode 110 and the second semiconductor layer 22 of the signal readout circuit thin film transistor 121 are configured by the Same semiconductor layer, and are formed simultaneously. The present process is a semiconductor film forming step of simultaneously forming the first semiconductor layer 12 and the second semiconductor layer 22. The structure and manufacturing method will be described by referencing FIGS. 17 to 24. FIG. 17 is a cross-sectional view of a photosensing portion 200 according to the second embodiment. FIGS. 18 to 24 are cross-sectional views of the photosensing portion 200 in each manufacturing step.

The photosensing portion 200 includes the photodiode 110 and the readout circuit 120. The readout circuit 120 includes the signal readout circuit thin film transistor 121. The photodiode 110 includes a Schottky diode having a Schottky barrier section S. The Schottky diode is the photodiode 110, which reacts to natural light L. The signal readout circuit thin film transistor 121 is a channel etch-type thin film transistor.

The photodiode 110 includes the first metal electrode 11, the first insulating layer 14, the first semiconductor layer 12, the first ohmic contact layer 13, the first transparent electrode 16 and the second insulating layer 17. The Schottky barrier section S is realized at the interface between the first metal electrode 11 and the first semiconductor layer 12. A Schottky diode defining a direction from the first metal electrode 11 to the first transparent electrode 16 as a forward direction is configured.

The glass substrate 1, for example, is a non-alkali glass, e.g., borosilicate glass. The glass substrate 1, for example, has a thickness of 0.5 to 0.7 mm. The first metal electrode 11 is arranged on the glass substrate 1. The first metal electrode 11 has a substantially oblong shape. The first metal electrode 11, for example, is an alloy of molybdenum and tantalum. The first metal electrode 11, for example, has a thickness of 200 nm.

The first insulating layer 14 is arranged so as to cover the first metal electrode 11 excluding the insulating layer removal portion RM1. Although the film forming step is described in detail later, the first insulating layer 14 is formed so as to cover the first metal electrode 11, and then a portion thereof is removed at the insulating layer removal portion RM1 on top of the first metal electrode 11. The first insulating layer 14, for example, is a silicon nitrate/silicon oxide (SiN/SiO₂) film. The first insulating layer 14, for example, has a thickness of 400 nm. The first semiconductor layer 12 is arranged on the first metal electrode 11. The first semiconductor layer 12, for example, has a substantially oblong shape. The first semiconductor layer 12, for example, is an amorphous silicon layer. The first semiconductor layer 12, for example, has a thickness of 200 nm. The first ohmic contact layer 13 is arranged on the first semiconductor layer 12. The first ohmic contact layer 13, for example, is an n+ amorphous silicon layer. The n− amorphous silicon layer, for example, has a thickness of 50 nm. The first transparent electrode 16 is arranged so as to cover over the first insulating layer 14 and the first ohmic contact layer 13. The first transparent electrode 16, for example, is a film of an oxide of an alloy of indium and titanium (ITO). The first transparent electrode 16, for example, has a thickness of 100 nm. The first transparent electrode 16 and the first ohmic contact layer 13 contact and are electrically connected. The second insulating layer 17 is arranged so as to cover the first transparent electrode 16.

The Schottky barrier section S is formed between the first metal electrode 11 and the first semiconductor layer 12. On the other hand, since the first ohmic contact layer 13 is present, the first transparent electrode 16, the first ohmic contact layer 13 and the first semiconductor layer 12 make ohmic contact, and a Schottky barrier is not produced. The first metal electrode 11, the first semiconductor layer 12, the first ohmic contact layer 13 and the first transparent electrode 16 constitute the Schottky diode. A schematic diagram of the diode circuit is depicted on the right of FIG. 17. As expressed in the present schematic diagram, a Schottky diode defining a direction from the first metal electrode 11 to the first transparent electrode 16 as a forward direction is realized.

The Schottky barrier section S is produced at the interface between the first metal electrode 11 and the first semiconductor layer 12. For this reason, the thickness of the first semiconductor layer 12 does not influence the realization of the Schottky barrier. For this reason, the thickness of the first semiconductor layer 12 can be thinned. In the present embodiment, for example, an amorphous silicon layer of 200 nm thickness is arranged. The thickness of the amorphous silicon layer is preferably 50 nm or more and 500 nm or less. In the case of establishing a PN-type diode rather than the Schottky barrier, for example, the amorphous silicon layer is thick on the order of 1 to 2 microns. In the photodiode 110 according to the present disclosure, the photosensing portion 200 having a wide light receiving portion can be realized with a simple configuration differing from PN type.

In the present embodiment, natural light L is incident from the side on which the first transparent electrode 16 is arranged, as shown in FIG. 17. The first transparent electrode 16 and the second insulating layer 17 have high transparency. The natural light L passes through the first transparent electrode 16 and the second insulating layer 17. The natural light L is incident on the interface between the first semiconductor layer 12 and the first metal electrode 11, where the Schottky barrier is realized. The natural light L is absorbed by the first semiconductor layer 12. The natural light L is incident from the side of the first transparent electrode 16 to the first semiconductor layer 12. Then, the charge carrier pairs of the Schottky barrier are released. The free charge carriers give rise to photoelectric current.

The readout circuit 120 includes the signal readout circuit thin film transistor 121 and the signal readout electrode 3. The signal readout circuit thin film transistor 121 includes the second metal electrode 21, the third insulating layer 24, the second semiconductor layer 22, the second ohmic contact layer 23, the metal source electrode 3a, the metal drain electrode 3b, the transparent source electrode 26a and the transparent drain electrode 26b constituting the second transparent electrode 26, and the fourth insulating layer 27. The source electrode has a configuration in which the metal source electrode 3a formed to extend in a branched manner from the signal readout electrode 3, and a transparent source electrode 26a configured by the second transparent electrode 26 are laminated. The drain electrode includes a configuration in which the metal drain electrode 3b formed in the same layer as the signal readout electrode 3 and the transparent drain electrode 26b configured by the second transparent electrode 26 are laminated.

The second metal electrode 21 is arranged on the glass substrate 1. The second metal electrode 21 and the first metal electrode 11 are formed simultaneously as described layer, and formed by the same layer. The present process is a metal electrode film forming step of simultaneously forming the first metal electrode 11 and the second metal electrode 21. The second metal electrode 21, for example, is an alloy of molybdenum and tantalum. The second metal electrode 21, for example, has a thickness of 200 nm. The second metal electrode 21 constitutes the scanning electrode 2 shown in FIG. 4. As shown in FIG. 4, a part of the scanning electrode 2 extends in a branched manner, and constitutes a portion of the signal readout circuit thin film transistor 121. This extending portion constitutes a first gate electrode 21a of the signal readout circuit thin film transistor 121.

The third insulating layer 24 is arranged over the second metal electrode 21 so as to cover the second metal electrode 21. The third insulating layer 24, for example, is a silicon nitride (SiN) film. The third insulating layer 24, for example, has a thickness of 400 nm. The third insulating layer 24 and the first insulating layer 14 are formed simultaneously as described later, and formed by the same layer. The present process is an insulating layer film forming step of simultaneously forming the first insulating layer 14 and the third insulating layer 24.

The second semiconductor layer 22 is arranged so as to cover the first gate electrode 21a in an island shape as shown in FIG. 4. The second semiconductor layer 22 is arranged over the third insulating layer 24 as shown in FIG. 17. As the second semiconductor layer 22, an amorphous silicon layer can be used, for example. A second ohmic contact layer 23 is provided over the amorphous silicon layer. The second ohmic contact layer 23, for example, is constituted by n+amorphous silicon. Although the details are described later, the first semiconductor layer 12 and the second semiconductor layer 22 are simultaneously formed and constituted by the same layer. The first ohmic contact layer 13 and the second ohmic contact layer 23 are simultaneously formed, and constituted by the same layer. The present process is an ohmic contact layer film forming step of simultaneously forming the first ohmic contact layer 13 and the second ohmic contact layer 23. The first semiconductor layer 12 and the second semiconductor layer 22, for example, have a thickness of 200 nm. The n+ amorphous silicon layer constituting the first ohmic contact layer 13 and the second ohmic contact layer 23 has a thickness of 50 nm, for example.

The signal readout electrode 3 is provided on the third insulating layer 24 and the second ohmic contact layer 23. The signal readout electrode 3, for example, is a metal electrode of chromium (Cr), aluminum (Al), titanium (Ti) or the like. As shown in FIG. 4, the signal readout electrode 3 extends in the up/down direction of the two-dimensional photosensor 100. A part of the signal readout electrode 3 extends in a horizontal direction in a branched manner, e. g., right direction in FIG. 4. The extending portion of the signal readout electrode 3 constitutes a portion of the readout circuit 120, as shown at the left end of FIG. 17.

The second transparent electrode 26 is provided at two locations sandwiching the first gate electrode 21a on the second ohmic contact layer 23, as shown in FIG. 4. One functions as the transparent source electrode 26a of the signal readout circuit thin film transistor 121, and the other functions as the transparent drain electrode 26b of the signal readout circuit thin film transistor 121. The transparent drain electrode 26b which is part of the second transparent electrode 26 conducts with the first transparent electrode 16. In the present embodiment, as described later, the second transparent electrode 26 and the first transparent electrode 16 are formed simultaneously, and are configured by the same layer. The present process is a transparent electrode film forming step of simultaneously forming the first transparent electrode 16 and the second transparent electrode 26. As shown in FIG. 17, the transparent drain electrode 26b which is part of the second transparent electrode 26 extends to become the first transparent electrode 16. The transparent drain electrode 26b is arranged on the first ohmic contact layer 13 so as to cover the first ohmic contact layer 13. The second transparent electrode 26 and the first transparent electrode 16 are films of an oxide of an alloy of indium and titanium (ITO). The first transparent electrode 16 and the second transparent electrode 26, for example, have a thickness of 100 nm.

The second ohmic contact layer 23 and the metal source electrode 3a, the transparent source electrode 26a and the metal drain electrode 3b, and the transparent drain electrode 26b are patterned to be arranged divided in two on the second semiconductor layer 22.

The fourth insulating layer 27 is arranged on the second transparent electrode 26. The fourth insulating layer 27 is configured by silicon nitride (SiN), for example. As described later, the second insulating layer 17 and the fourth insulating layer 27 are simultaneously formed, and configured by the same layer. The present process is an insulating layer film forming step of simultaneously forming the second insulating layer 17 and the fourth insulating layer 27.

The natural light L is incident on the photodiode 110, and photoelectric current is realized in the photodiode 110. The ON voltage (for example, 15 V) is applied to the first gate electrode 21a, and the transparent drain electrode 26b and the transparent source electrode 26a enter a conductive state. The photoelectric current is transmitted to the signal processing circuit 150 from the first transparent electrode 16 through the second transparent electrode 26, the transparent drain electrode 26b, the transparent source electrode 26a and the signal readout electrode 3.

The manufacturing method of the photosensing portion 200 shown in FIG. 17 will be described while referencing FIG. 4 and FIGS. 18 to 24. FIGS. 18 to 24 are cross-sectional views of the respective manufacturing steps, sectioning the photosensing portion 200 along the line I-I′ in FIG. 4.

As shown in FIG. 18, the first metal electrode 11 and the second metal electrode 21 are formed simultaneously on the glass substrate 1. For example, a metal thin film of chrome, aluminum, titanium or the like is formed by sputtering. The metal thin film, for example, has a thickness of about 200 nm. A photoresist is coated on this thin film. The pattern of the metal thin film is formed by the photolithography method. For example, the metal thin film of a portion not covered by the resist is etched by a chlorine-based dry etching method. The first metal electrode 11, for example, has the pattern shown in the plan view of FIG. 4. The second metal electrode 21, for example, has the pattern shown in the plan view of FIG. 4. The present process is a metal electrode film forming step of simultaneously forming the first metal electrode 11 and the second metal electrode 21.

Next, as shown in FIG. 19, the first insulating layer 14 and the third insulating layer 24 are formed simultaneously. The first insulating layer 14 and the third insulating layer 24 are configured by the same layer. The present process is an insulating layer film forming step of simultaneously forming the first insulating layer 14 and the third insulating layer 24. The first insulating layer 14 and the third insulating layer 24, for example, are SiN films. The SiN films, for example, are formed by a plasma CVD method or the like. The SiN film, for example, is patterned by SF₆-based dry etching. In particular, a part of the first metal electrode 11 is patterned so as to be exposed. In the photodiode 110, a second contact portion C2 is formed on the first metal electrode 11.

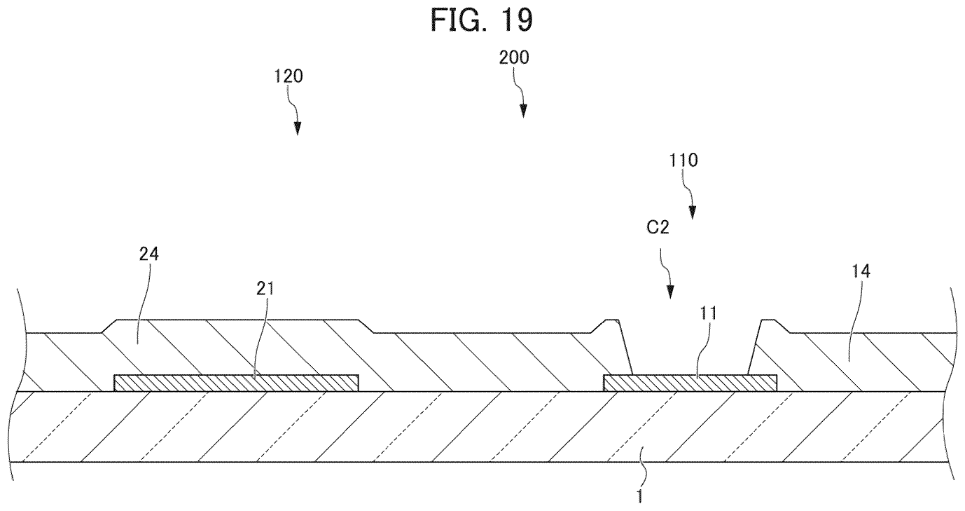

Next, as shown in FIG. 20, the first semiconductor layer 12 and the second semiconductor layer 22, as well as the first ohmic contact layer 13 and the second ohmic contact layer 23 are laminated in succession to configure a laminate body. The first semiconductor layer 12 and the second semiconductor layer 22 are simultaneously formed, and configured by the same layer. The present process is a semiconductor layer film forming step of simultaneously forming the first semiconductor layer 12 and the second semiconductor layer 22. The first ohmic contact layer 13 and the second ohmic contact layer 23 are simultaneously formed, and configured by the same layer. The present process is an ohmic contact layer film forming step of simultaneously forming the first ohmic contact layer 13 and the second ohmic contact layer 23. The first semiconductor layer 12 and the second semiconductor layer 22, for example, are amorphous silicon (a-Si) layers. The first ohmic contact layer 13 and the second ohmic contact layer 23, for example, are n+amorphous silicon (n+ a-Si) layers. The laminate body is patterned into an island shape through a SF₆-based dry etching process step. The island-shaped pattern of the laminate body is shown in FIG. 4, for example. The first semiconductor layer 12 and the first ohmic contact layer 13 overlap with the island-shaped pattern of the first metal electrode 11, and have the same or smaller areas than the island-shaped pattern of the first metal electrode 11.

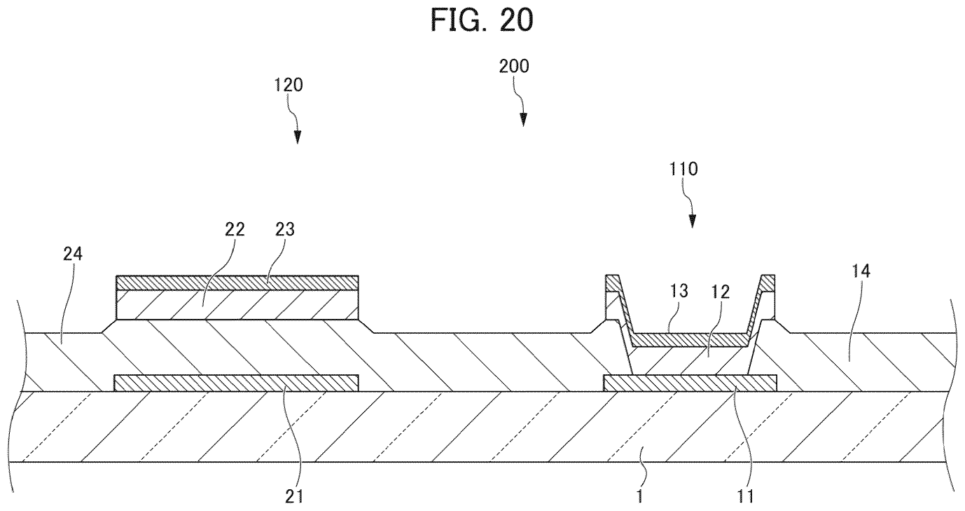

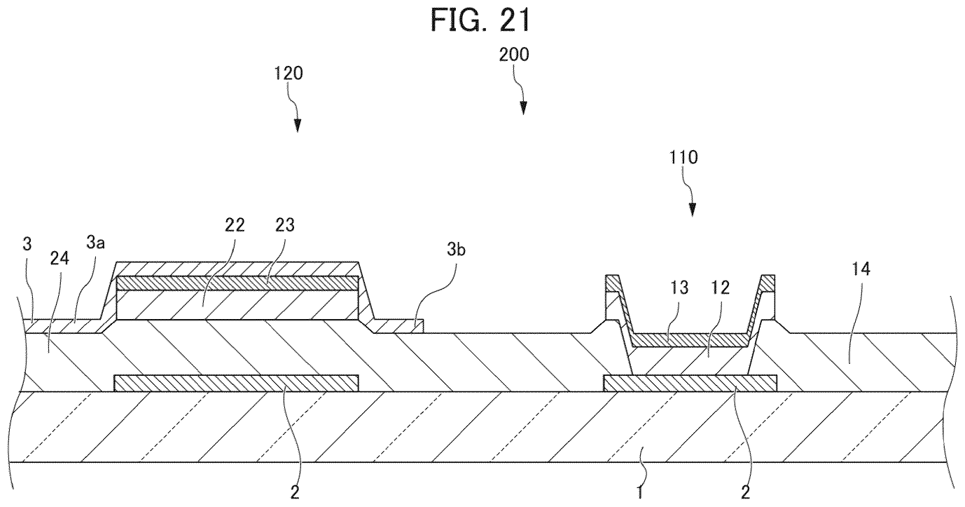

Next, as shown in FIG. 21, the signal readout electrode 3 is formed. The signal readout electrode 3, for example, is a metal thin film of chromium (Cr), aluminum (Al), titanium (Ti) or the like. After the metal thin film is formed, it is patterned by chlorine-based dry etching. The signal readout electrode 3 is extended in a branched-manner as shown in FIG. 4, and arranged on the second semiconductor layer and the second ohmic contact layer 23. The extending portion from the signal readout electrode 3 constitutes the metal source electrode 3a and the metal drain electrode 3b of the signal readout circuit thin film transistor 121, as described later.

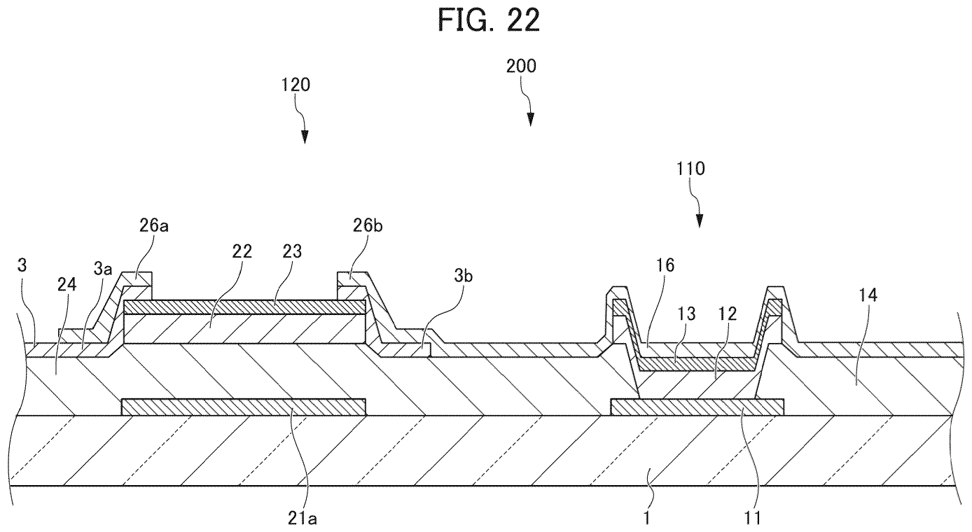

Next, as shown in FIG. 22, the first transparent electrode 16 and the second transparent electrode 26 are formed simultaneously. The first transparent electrode 16 and the second transparent electrode 26 are configured by the same layer. The present process is a transparent electrode film forming step of simultaneously forming the first transparent electrode 16 and the second transparent electrode 26. The first transparent electrode 16 is arranged in an island shape on the first semiconductor layer 12 and the first ohmic contact layer 13 as shown in FIG. 4. On the other hand, in the second transparent electrode 26 and the signal readout electrode 3, a part of the portions arranged over the first gate electrode 21a is patterned. Patterning is conducted by chlorine-based dry etching, for example. The second transparent electrodes 26 are arranged to be separated at two locations sandwiching the first gate electrode 21a constituted by the second metal electrode 21 therebetween, as shown in FIGS. 4 and 22. One second transparent electrode 26 functions as the transparent source electrode 26a, and the other second transparent electrode 26 functions as the transparent drain electrode 26b. The first transparent electrode 16 and the transparent drain electrode 26b which is part of the second transparent electrode 26 are integral, and electrically conducting.

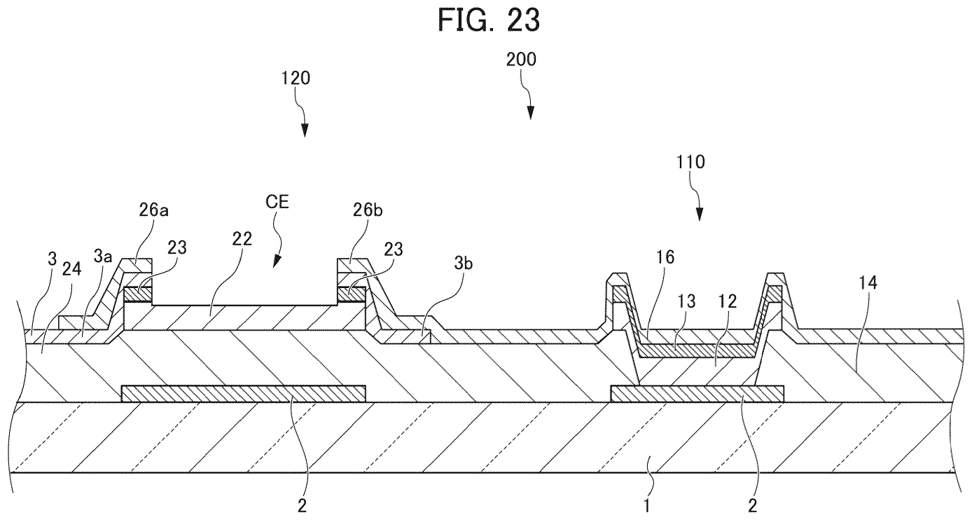

Next, as shown in FIG. 23, a part of the second ohmic contact layer 23 and the second semiconductor layer 22 are patterned with the transparent source electrode 26a and the transparent drain electrode 26b constituted from the second transparent electrode 26 as a mask or resist. The channel etching portion CE is formed. SF₄-based dry etching can be used, for example. This method is a system generally called a channel etching system. Precise management of the etching end time of SF₆-based dry etching is necessary. Since there is no etching stopper, there is a possibility of not only the n+amorphous silicon, but amorphous silicon being etched away. It is necessary to manage the end point of etching so that amorphous silicon is not etched away.

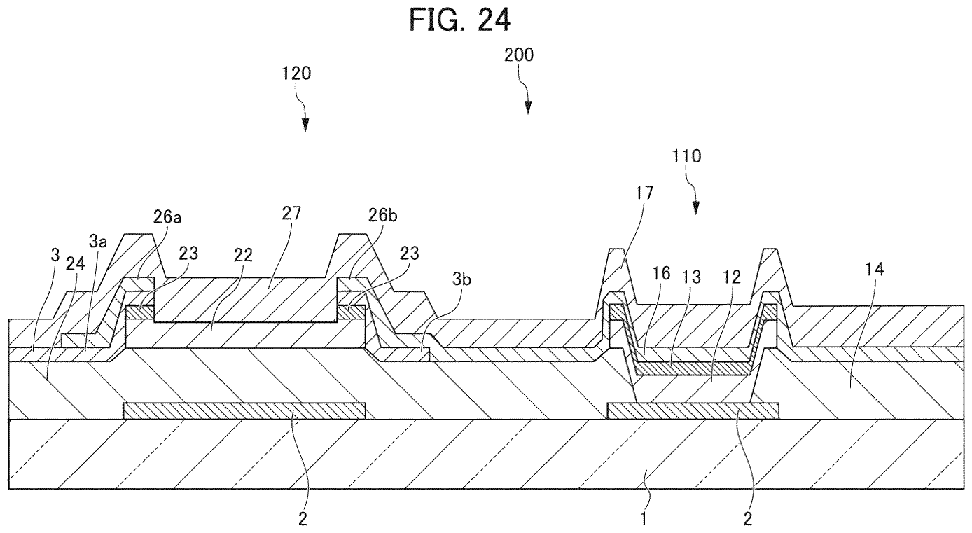

Finally, as shown in FIG. 24, the second insulating layer 17 and the fourth insulating layer 27 are formed simultaneously. The second insulating layer 17 and the fourth insulating layer 27 are configured by the same layer. The present process is an insulating layer film forming step of simultaneously forming the second insulating layer 17 and the fourth insulating layer 27. The second insulating layer 17 and the fourth insulating layer 27, for example, are silicon nitride (SiN), and are formed by a plasma CVD method, for example.

Although a description has been omitted thus far, wiring reconnection is performed in the extraction of signals. Contact holes are provided in the insulating layer as appropriate, whereby the conducting layers of different layers are brought into contact.

### Second Modified Example

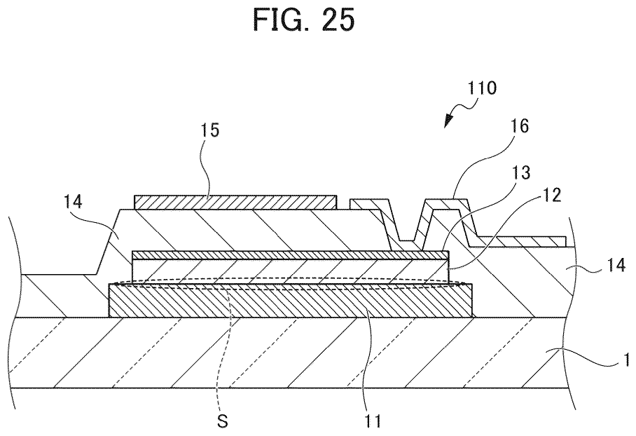

FIG. 25 is a cross-sectional view of a photodiode 110 according to a second modified example. A fifth insulating layer 15 is further arranged on the first insulating layer 14 disclosed in the above-mentioned embodiments. The fifth insulating layer 15 is a dielectric layer. The first insulating layer 14 is configured by silicon nitride (SiN). The fifth insulating layer 15 is configured by silicon oxide (SiO₂). The fifth insulating layer 15 is formed on the top surface of the photodiode 110 on the opposite side to the glass substrate 1. The fifth insulating layer 15 has a function of reducing the surface reflection. A low-reflection structure is realized by phase difference adjustment (index matching). Upon the natural light L being incident, it is possible to suppress reflection of natural light L at the surface of the first insulating layer 14. The fifth insulating layer 15, for example, has a refractive index of 1.5 and a thickness of 90 nm. The luminous energy reaching the Schottky barrier section S thereby increases, and the Sensitivity of the photodiode 110 improves.

### Third Modified Example

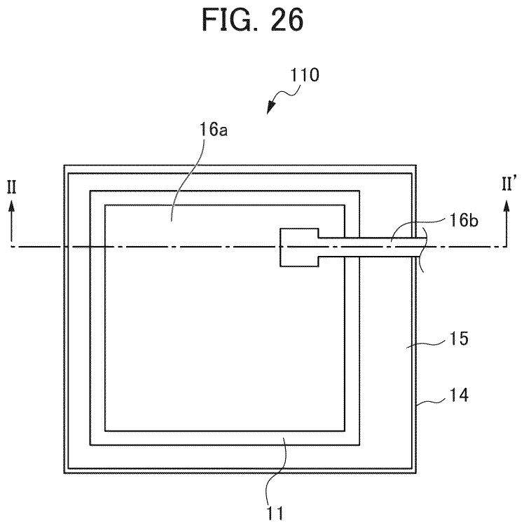

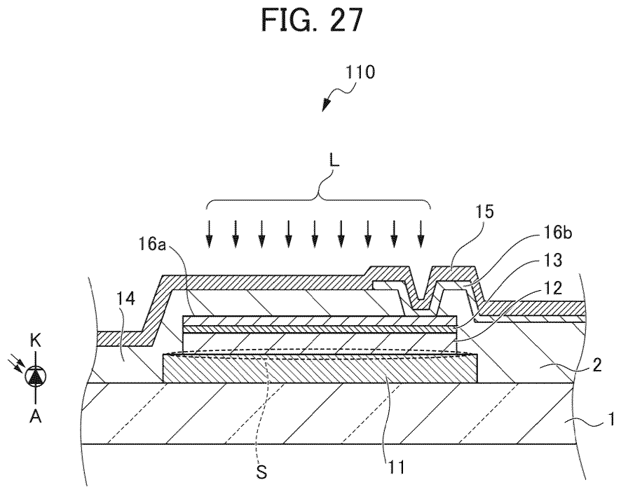

FIGS. 26 and 27 show examples of a photodiode 110 according to a third modified example. FIG. 26 is a plan view. FIG. 27 is a cross-sectional view sectioning along the cross-section line II-II′ shown in FIG. 26. In the third modified example, the fifth insulating layer 15 is arranged wider than the second modified example shown in FIG. 25. In FIG. 26, since the fifth insulating layer 15 is transparent, the notations of the first transparent electrode 16b, etc. is not a dotted line, but rather noted by solid lines. The fifth insulating layer 15, for example, is configured from silicon oxide (SiO₂). The fifth insulating layer 15 is arranged so as to cover the first insulating layer 14 and the first transparent electrode 16 (first transparent electrode 16b which is the upper layer and the first transparent electrode 16a which is the lower layer). Other than the portion where the first transparent electrode 16b which is the upper layer is formed, silicon nitride (SiN) and silicon oxide (SiO₂) are arranged by laminating. When natural light L is incident, the reflection of natural light L at the surface of the first insulating layer 14 and the first transparent electrode 16 can be reduced. The luminous energy reaching the Schottky barrier section S thereby increases, and the sensitivity of the photodiode 110 improves.

### Fourth Modified Example

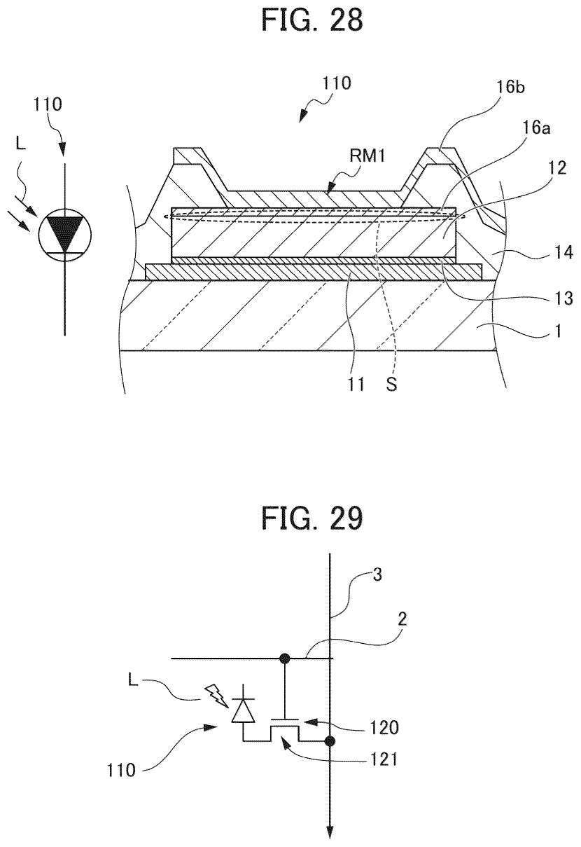

FIG. 28 is a cross-sectional view sectioning the photodiode 110 according to a fourth modified example along the cross-section line I-I′ shown in FIG. 4. In the above-mentioned embodiment, the first semiconductor layer 12 is laminated on the first metal electrode 11, and the first ohmic contact layer 13 is laminated on the first semiconductor layer 12. In the fourth modified example, the first ohmic contact layer 13 is laminated on the first metal electrode 11, and the first Semiconductor layer 12 is laminated on the first ohmic contact layer 13. The first transparent electrode 16a which is the lower layer is laminated on the first semiconductor layer 12. The first insulating layer 14 is formed, and a part contacting the first transparent electrode 16a which is the lower layer is removed, whereby the insulating layer removal portion RM1 is formed. The first transparent electrode 16b which is the upper layer is arranged to cover the insulating layer removal portion RM1. The first transparent electrode 16b which is the upper layer and the first transparent electrode 16a which is the lower layer are electrically connected.

The materials constituting the first metal electrode 11, the first semiconductor layer 12, the first ohmic contact layer 13, the first insulating layer 14 and the first transparent electrode 16 are the same as the materials described in the above-mentioned embodiment.

In the fourth modified example, the Schottky barrier section S is produced at the interface between the first semiconductor layer 12 and the first transparent electrode 16a. The forward direction of the photodiode 110 is a direction from the first transparent electrode 16 to the first metal electrode 11, as shown on the left of FIG. 28. As shown in FIG. 29, the photodiode 110 which is the reverse direction to the drain electrode of the signal readout circuit thin film transistor 121 is formed. In the photodiode 110, a reverse bias must be applied. In the first embodiment, the reference voltage Vb shown in FIG. 1 was −1 V. In contrast, the reference voltage Vb according to the fourth modified example is +3 V, for example.

The signal readout circuit thin film transistor 121 relating to the photodiode 110 according to the fourth modified example preferably uses the IGZO of the first embodiment. The manufacturing process described in the first embodiment can be followed. The second embodiment uses amorphous silicon as the second semiconductor layer 22, similarly to the fourth modified example. However, the lamination sequence of n+ amorphous silicon differs from the fourth modified example. In the second embodiment, a reverse stagger-type thin film transistor can be used. It is difficult to change the lamination sequence of the second semiconductor layer 22 and the second ohmic contact layer 23. For this reason, in the fourth modified example, it is difficult to standardize the manufacturing steps as in the second embodiment. In the fourth modified example, it is preferable to follow the first embodiment.

### Fifth Modified Example

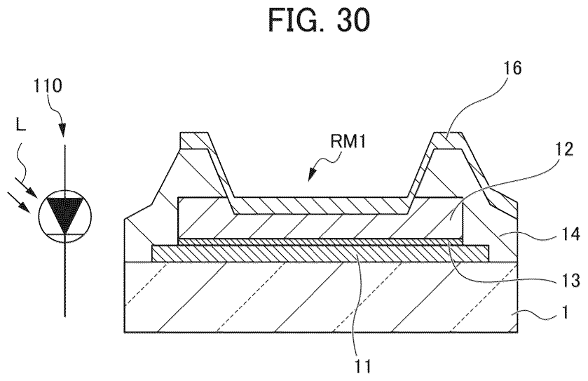

FIG. 30 is a cross-sectional view of a photodiode 110 according to a fifth modified example. In the fourth modified example, the first transparent electrode 16a which is the lower layer was arranged. In the fifth modified example, the first transparent electrode 16a which is the lower layer is not arranged. In the fourth modified example, the first transparent electrode 16a which is the lower layer functions as an etching stopper. Removal of the first insulating layer 14 is not linked to removal of the first semiconductor layer 12, e.g., the amorphous silicon. In the fifth modified example, since there is no function of an etching stopper, the first semiconductor layer 12 is partially etched. In FIG. 30, the upper part of the first semiconductor layer 12 is etched, whereby the first semiconductor layer 12 has a concave shape. The first ohmic contact layer 13, for example, is n+ amorphous silicon, and the thickness thereof is thin at 50 nm, for example. For this reason, in the first embodiment, the first transparent electrode 16a which is the lower layer is arranged as shown in FIG. 6. In contrast, the first semiconductor layer 12, e.g., the amorphous silicon layer, has a thickness of 200 nm, for example. The first semiconductor layer 12 is thick compared to the first ohmic contact layer 13. For this reason, as shown in FIG. 30, there is not a high necessity for precise control of etching to prevent all of the first semiconductor layer 12 from being etched. The fifth modified example, as shown in FIG. 30, has advantages in that the first transparent electrode 16a which is the lower layer shown in FIG. 28 is unnecessary, and thus the process is short.

### Sixth Modified Example

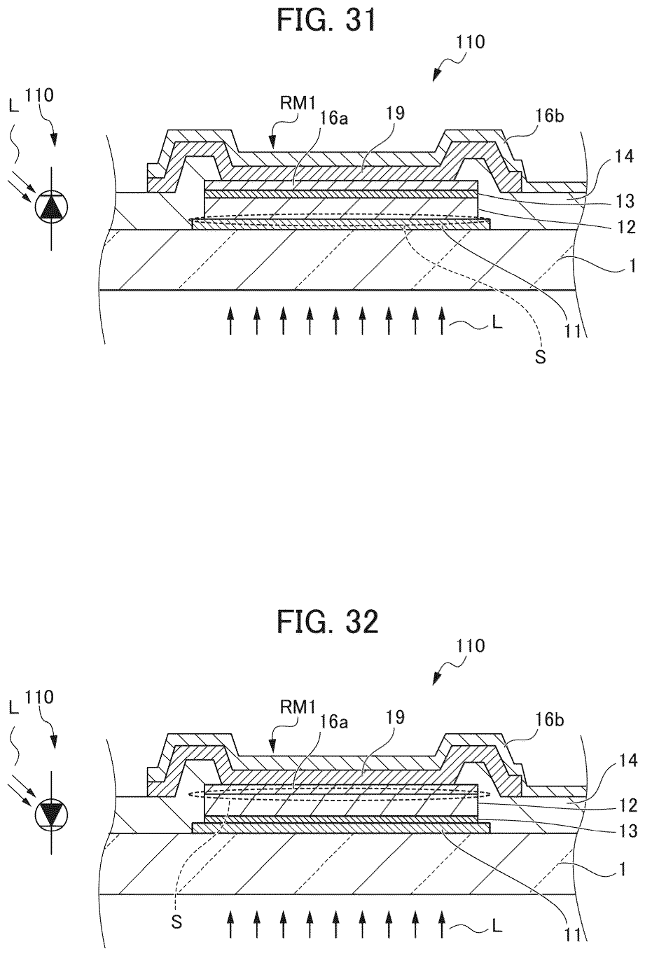

FIG. 31 is a cross-sectional view of a photodiode 110 according to a sixth modified example. In the above-mentioned embodiment, the photodiode 110 receives the natural light L incident on the opposite side to the glass substrate 1. The photodiode 110 according to the sixth modified example receives the natural light L incident from the side of the glass substrate 1. The first metal electrode 11 is configured by a transparent electrode. The natural light L is incident from the side of the transparent first metal electrode 11 to the first semiconductor layer 12. The first metal electrode 11, for example, AZO in which aluminum (Al) is doping zinc oxide is preferable. A zinc oxide (ZnO) transparent conductive film, gallium doped GZO or ITO film may be adopted.

The first semiconductor layer 12, the first ohmic contact layer 13 and the first transparent electrode 16a which is the lower layer are laminated in this order on the first metal electrode 11, patterned and arranged. Next, the first insulating layer 14 is laminated and patterned. The insulating layer removal portion RM1 is formed on the first transparent electrode 16a which is the lower layer. The fourth metal electrode 19 is arranged so cover the insulating layer removal portion RM1. The first transparent electrode 16b which is the upper layer is formed on the fourth metal electrode 19. The first semiconductor layer 12, for example, is an amorphous silicon layer. The first ohmic contact layer 13, for example, is an n+ amorphous silicon layer. The first transparent electrode 16a which is the lower layer and the first transparent electrode 16b which is the upper layer, for example, are ITO layers. The fourth metal electrode 19, for example, is chromium (Cr), aluminum (Al), titanium (Ti) or the like. The fourth metal electrode 19 may be formed simultaneously with the metal source electrode 3a and the metal drain electrode 3b of the signal readout circuit thin film transistor 121, and configured by the same layer. The present process is a metal electrode film forming step of simultaneously forming the fourth metal electrode 19, the metal source electrode 3a and the metal drain electrode 3b.

The natural light L incident from the opposite side to the glass substrate 1 is shielded by the fourth metal electrode 19. On the other hand, the natural light L incident from the side of the glass substrate 1 passes through the first metal electrode 11, and reaches the Schottky barrier section S formed at the interface between the first metal electrode 11 and the first semiconductor layer 12. The natural light L is received, whereby the photodiode 110 generates photoelectric current. The natural light L incident from the side of the glass substrate 1 passes through the Schottky barrier section S, then reflects at the fourth metal electrode 19 to be incident on the Schottky barrier section S again. Since the natural light L passes through the Schottky barrier section S twice, a photodiode 110 having high sensitivity can be realized.

### Seventh Modified Example

In the sixth modified example, the incident natural light L is received from the side of the glass substrate 1, and the first ohmic contact layer 13 is provided to the first semiconductor layer 12 on the opposite side to the glass substrate 1. As shown in FIG. 32, the incident natural light L is received from the side of the glass substrate 1, and the first ohmic contact layer 13 may be provided to the first semiconductor layer 12 on the side of the glass substrate 1. The position of the first ohmic contact layer 13 relative to the first semiconductor layer 12 may be provided on the opposite side to the position shown in the above-mentioned embodiment and modified examples thereof. In these cases, the orientation of the Schottky diode changes as shown in FIG. 29, and the reference voltage Vb changes from −1 V to +3 V, for example.

### Eighth Modified Example

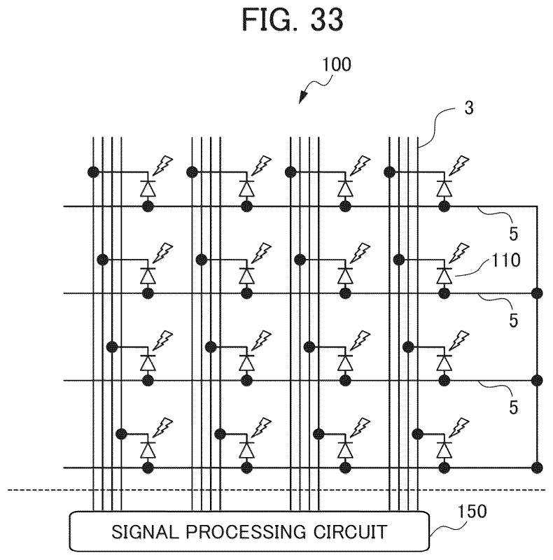

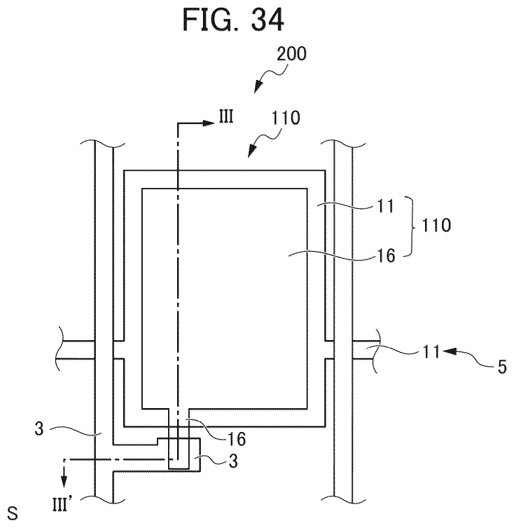

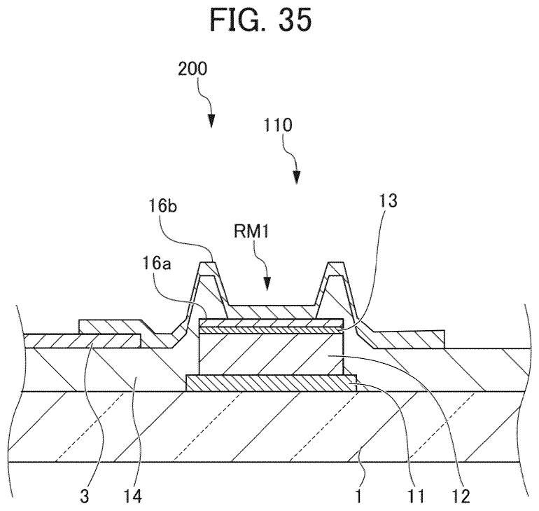

In the two-dimensional photosensor 100 according to the above-mentioned embodiment, photoelectric current from the photodiode 110 is detected through the signal readout circuit thin film transistor 121. This is called an active matrix system. The eighth modified example discloses a two-dimensional photosensor 100 based on a direct drive system. The eighth modified example will be described by referencing FIGS. 33 to 35. FIG. 33 is a circuit diagram showing an overview of the two-dimensional photosensor 100. FIG. 34 is a plan view of the photosensing portion 200. FIG. 35 is a cross-sectional view sectioning along the line III-III′ in FIG. 34.

As shown in FIG. 33, the anode of the photodiode 110 is connected to a common electrode 5 provided in plurality in the horizontal direction. The common electrode 5 is the first metal electrode 11 shown in FIG. 35. As shown in FIGS. 33 and 34, the common electrode 5 extends in the left/right direction. The cathode of the photodiode 110 is connected to the first transparent electrode 16. As shown in FIG. 34, the first transparent electrode 16 is connected to the signal readout electrode 3. The signal readout electrode 3 extends in the up/down direction as shown in FIGS. 33 and 34. The signal readout electrode 3 is connected to the signal processing circuit 150, as shown in FIG. 33. The signal processing circuit 150 detects the in-plane distribution of the intensity of light incident on each photodiode 110 from the signals of each photodiode 110.

The direct drive system described by referencing FIGS. 33 to 35 has an advantage in that the signal readout circuit thin film transistor 121 is unnecessary. Apart from the glass substrate 1 on which the two-dimensional photosensor 100 is mounted, the signal processing circuit 150 can be realized using a silicon integrated circuit (Si-IC).

As shown in FIG. 35, the first metal electrode 11, the first semiconductor layer 12, the first ohmic contact layer 13 and the first transparent electrode 16a which is the lower layer are arranged by laminating in this order on the glass substrate 1. These layers are batch patterned and arranged in an island shape as shown in FIG. 34. Furthermore, the first insulating layer 14 is arranged. A part of the first insulating layer 14 on the first transparent electrode 16a which is the lower layer is removed, whereby the insulating layer removal portion RM1 is formed and arranged. The signal readout electrode 3 is provided and patterned on the first insulating layer 14. The first transparent electrode 16b which is the upper layer is laminated and patterned so as to cover the insulating layer removal portion RM1, and overlap the signal readout electrode 3.

The materials constituting the glass substrate 1, the first metal electrode 11, the first semiconductor layer 12, the first ohmic contact layer 13, the first transparent electrode 16 and the first insulating layer 14 are similar to the above-mentioned embodiment.

### Ninth Modified Example

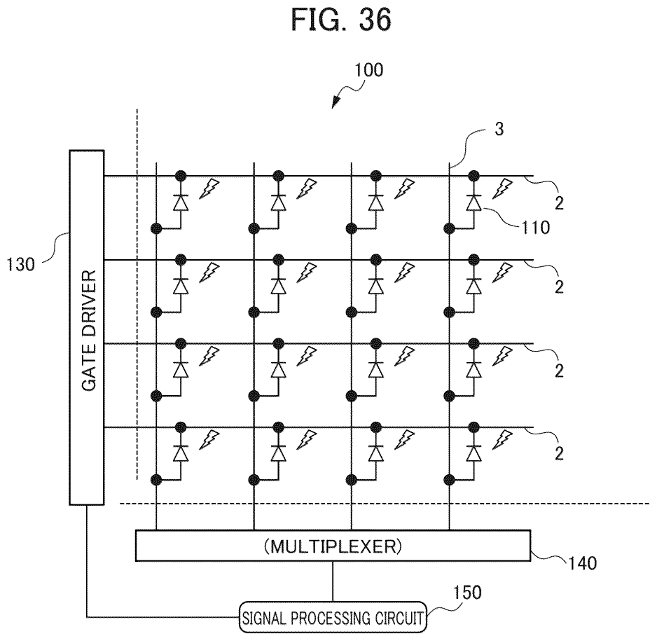

The direct drive system was described in the eighth modified example. A simple matrix (Passive Matrix) system may be adopted. FIG. 36 is an overall circuit diagram of a two-dimensional photosensor 100 according to a ninth modified example. A scan signal is applied to the scanning electrode 2 by the gate driver 130. For example, the voltage during scanning is +4 V. From the multiplexer 140, for example, a voltage +1.5 V is applied, and reverse bias voltage of 2.5 V is applied to the photodiode 110. In response to the illuminance on each photodiode 110, the photoelectric current is generated as shown in FIG. 2. Based on the generated photoelectric current, the signal processing circuit 150 deduces the light illuminance. When not scanning, a voltage of +1.1 V is applied to the scanning electrode 2. At this time, a forward voltage of 0.4 V is applied to the photodiode 110. At this time, as shown in FIG. 2, irrespective of the illuminance to each photodiode 110, the photoelectric current is suppressed. The photoelectric current from the scanned photodiode 110 is provided to the multiplexer 140 and the signal processing circuit 150. The illuminance at each photodiode 110 is estimated by scanning the scanning electrode 2.

The above described two-dimensional photosensor 100 is preferably applied to a display. The display, for example, is a liquid crystal display, organic EL display, or the like. The two-dimensional photosensor 100 according to the present invention is provided to the glass substrate 1, for example. This glass substrate 1 may be an independent glass substrate 1, or may be the glass substrate 1 possessed by a display. A mode providing the two-dimensional photosensor 100 to the independent glass substrate 1 and combining with the display is generally called an on-cell system. A mode providing the two-dimensional photosensor 100 to the glass substrate 1 possessed by the display as the glass substrate 1 is generally called an in-cell system. The two-dimensional photosensor 100 according to the present invention can be applied to both the on-cell system and in-cell system. In the on-cell system, the two-dimensional photosensor 100 is manufactured and driven independently from the display main body. For this reason, application to a large-scale display can also be expected.

The present disclosure allows for various embodiments and modifications without departing from the broad sense of spirit and scope of the present invention. Additionally, the aforementioned embodiments are for explaining the present invention, and are not to limit the scope of the present invention. In other words, the scope of the present invention is shown not by the embodiments, but rather by the scope of the claims. Then, various modifications conducted within the scope of the claims and within the scope of the meaning of the equivalent disclosures thereto are regarded as within the scope of the present invention.

The following such effects are exerted by the two-dimensional photosensor 100 according to the above described embodiments.

(1) A two-dimensional photosensor 100 includes a plurality of arrayed photodiodes 110, in which the photodiodes 110 each include a laminate of a first metal electrode 11; a first semiconductor layer 12; a first ohmic contact layer 13; and a first transparent electrode 16, in which the first semiconductor layer 12 and the first ohmic contact layer 13 are arranged between the first metal electrode 11 and the first transparent electrode 16, a Schottky barrier is provided at an interface between the first semiconductor layer 12 and the first metal electrode 11, or at an interface between the first semiconductor layer 12 and the first transparent electrode 16, and the photosensor senses light incident from a side of the first transparent electrode 16 toward the first semiconductor layer 12.

The two-dimensional photosensor 100 capable of gradation detection over a relatively wide two-dimensional space such as of a display is thereby provided. By detecting a two-dimensional distribution of shade, brightness, etc. on a display, and providing this as feedback to a display signal of the display, it enables display including the realization of actual shade and shadow, and thus it is possible to further approach the real thing such as paper. The brightness of only bright areas on the display portion can be raised to ensure visibility. An easy to see display can be realized with low power consumption.

(2) In the two-dimensional photosensor 100 of (1), the first semiconductor layer 12 consists of amorphous silicon, and the first ohmic contact layer 13 consists of n+amorphous silicon.

It is thereby possible to manufacture even in a factory without a P+ process of adding acceptor atoms as impurities. It is possible to manufacture the two-dimensional photosensor 100 in the same manufacturing process as a process for handling existing amorphous silicon thin film transistors. The addition of new manufacturing processes or modification thereto are unnecessary. In a conventional photosensor, e. g., the PIN-type amorphous silicon sensor such as of a solar cell, in order to enhance the sensitivity to light, it is necessary to raise the absorption of light by thickening the film thickness of the amorphous silicon layer to on the order from 1 to 2 microns. In contrast, with the Schottky diode of the present disclosure, since carriers are generated at the “narrow interface” of metal and semiconductor, it is not necessary to thicken the amorphous silicon film overall. Therefore, it is possible to obtain high sensitivity even with a thin amorphous silicon film on the order of several 100 nm generally used in an amorphous silicon thin film transistor factory. Since it is unnecessary to thicken the amorphous silicon layer, it is possible to make manufacture more efficient and thus produce at lower cost.

(3) In the two-dimensional photosensor 100 of (1) or (2), the first metal electrode 11 has a light shielding property, and includes a configuration extending out of a light sensing region.

Light incident from the side of the glass substrate 1 is thereby shielded. Then, only the detection of natural light L incident from the opposite side to the glass substrate 1 can be carried out. The natural light L is reflected at the first metal electrode 11, and passes twice through the interface between the first metal electrode 11 and the first semiconductor layer 12 formed by a Schottky barrier, and thus sensitivity improves. The first metal electrode 11 serves as both a light shield and a lead-out wire. It is thereby possible to achieve lowered cost with high productivity.

(4) In the two-dimensional photosensor 100 of any of (1) to (3), photoelectric current of each of the photodiodes 110 is individually acquired through direct connection, or acquired by scanning through a simple matrix system.

The two-dimensional photosensor 100 having high productivity and low cost is thereby obtained.

(5) The two-dimensional photosensor 100 of any of (1) to (4) further includes a readout circuit 120 that reads a signal of the photodiode 110, in which the readout circuit 120 includes a signal readout circuit thin film transistor 121, and the signal readout circuit thin film transistor 121 includes at least one layer consisting of a layer which is the same as a layer constituting the photodiode 110.

It is thereby possible to manufacture the two-dimensional photosensor 100 and the signal readout circuit thin film transistor 121 on an existing display manufacturing line. It is possible to achieve both high-sensitivity photosensor and high productivity by application of a thin amorphous silicon (a-Si) film.

(6) In the two-dimensional photosensor 100 of (5), the signal readout circuit thin film transistor 121 includes a second metal electrode 21, the second metal electrode 21 functions as a gate electrode of the signal readout circuit thin film transistor 121, and the second metal electrode 21 consists of a layer which is the same as the first metal electrode 11 of the photodiode 110, and is not electrically connected with the first metal electrode 11.

The manufacturing process is thereby shortened. Manufacturing by an existing thin film transistor factory is possible.

(7) In the two-dimensional photosensor 100 of (5) or (6), the signal readout circuit thin film transistor 121 includes a source electrode and a drain electrode, and the source electrode and the drain electrode at least include a layer which is the same as the first transparent electrode 16 possessed by the photodiode 110 or the first metal electrode 11.

The manufacturing process is thereby shortened. Manufacturing by an existing thin film transistor factory is possible.

(8) In the two-dimensional photosensor 100 of any of (5) to (7), the signal readout circuit thin film transistor 121 includes a second semiconductor layer 22, and the second semiconductor layer 22 consists of a layer that is the same as a first semiconductor layer 12 possessed by the photodiode 110.

Using a layer consisting of the same semiconductor in both the signal readout circuit thin film transistor 121 and the photodiode 110, it is thereby possible to obtain a photosensor having even higher sensitivity. Since it is possible to adopt a thin amorphous silicon film at about 1/10 of the amorphous silicon layer used in a solar cell, high productivity can be achieved at the same time.

(9) In the two-dimensional photosensor 100 of any of (5) to (8), the signal readout circuit thin film transistor 121 includes a second semiconductor layer 22 consisting of an indium gallium zinc oxide.

In the signal readout circuit thin film transistor 121, high mobility is thereby realized with a large surface area. The arrangement of the readout circuit 120 and photodiode 110 on the entire display surface becomes possible.

(10) In the two-dimensional photosensor 100 of any of (1) to (9), the photodiode 110 includes a dielectric layer which reduces surface reflection at an outermost surface on a side opposite to a glass substrate 1.

The luminous energy reaching the Schottky barrier section S thereby increases, and the sensitivity of the photodiode 110 improves.

(11) In a manufacturing method of a two-dimensional photosensor 100, the two-dimensional photosensor 100 including a plurality of arrayed photodiodes 110, and a readout circuit of signals from the photodiodes 110, the photodiodes 110 each including a laminate of a first metal electrode 11, a first semiconductor layer 12, a first ohmic contact layer 13, and a first transparent electrode 16, in which the first semiconductor layer 12 and the first ohmic contact layer 13 are arranged between the first metal electrode 11 and the first transparent electrode 16, a Schottky barrier is provided at an interface between the first semiconductor layer 12 and the first metal electrode 11, or at an interface between the first semiconductor layer 12 and the first transparent electrode 16, the photosensor senses light incident from a side of the first transparent electrode 16 toward the first semiconductor layer 12, and the signal readout circuit includes a signal readout circuit thin film transistor 121, the manufacturing method of a two-dimensional photosensor 100 includes a step of simultaneously forming at least one layer constituting the photodiode 110 and the signal readout circuit thin film transistor 121.

The two-dimensional photosensor 100 capable of gradation detection over an entire display surface is thereby provided. By detecting a two-dimensional distribution of shading, brightness, etc. on a display, and providing this as feedback to a display signal of the display, it enables display going so far as to realize actual shading and shadows, and thus it is possible to get closer to the real article such as paper.

(12) In the manufacturing method of a two-dimensional photosensor 100 of (11), the signal readout circuit thin film transistor 121 includes: a second metal electrode 21; a second semiconductor layer 22; a second ohmic contact layer 23; a transparent source electrode 26a and a transparent drain electrode 26b, the method includes at least any one step among: a metal electrode film forming step of simultaneously forming the first metal electrode 11 and the second metal electrode 21, or a metal electrode film forming step of simultaneously forming the first metal electrode 11, the transparent source electrode 26a and the transparent drain electrode 26b; a semiconductor layer film forming step of simultaneously forming the first semiconductor layer 12 and the second semiconductor layer 22; an ohmic contact layer film forming step of simultaneously forming the first ohmic contact layer 13 and the second ohmic contact layer 23; and a transparent electrode film forming step of simultaneously forming the first transparent electrode 16, the transparent source electrode 26a and the transparent drain electrode 26b.

The manufacturing process is thereby shortened. Manufacturing by an existing thin film transistor factory is possible.

(13) In the manufacturing method of a two-dimensional photosensor 100 of (11) or (12), the first semiconductor layer 12 contains amorphous silicon, and the first ohmic contact layer 13 contains n+ amorphous silicon.

It is thereby possible to manufacture the two-dimensional photosensor 100 in the same manufacturing process as a process for handling existing amorphous silicon thin film transistors. The addition of new manufacturing processes or modification thereto are unnecessary. In a conventional photosensor, e.g., the PIN-type amorphous silicon sensor such as of a solar cell, in order to enhance the sensitivity to light, it is necessary to raise the absorption of light by thickening the film thickness of the amorphous silicon layer to on the order of 1 to 2 microns. In contrast, with the Schottky diode of the present disclosure, since carriers are generated at the “narrow interface” of metal and semiconductor, it is not necessary to thicken the amorphous silicon film overall. Therefore, it is possible to obtain high sensitivity even with a thin amorphous silicon film on the order of several 100 nm generally used in an amorphous silicon thin film transistor factory.

(14) In the manufacturing method of a two-dimensional photosensor 100 of (11), a first semiconductor layer 12 contains an amorphous silicon layer, a first ohmic contact layer 13 contains an n+ amorphous silicon layer, a signal readout circuit thin film transistor 121 includes: a second metal electrode 21 arranged on a glass substrate 1, and functioning as a gate electrode; a second semiconductor layer 22 consisting of an IGZO layer; and a second transparent electrode 26 arranged on the second semiconductor layer 22, and functioning as a source electrode and a drain electrode, the manufacturing method of the two-dimensional photosensor 100 including: a metal electrode film forming step of simultaneously forming the first metal electrode 11 and the second metal electrode 21; and a transparent electrode film forming step of simultaneously forming the first transparent electrode 16 and the second transparent electrode 26.

In the signal readout circuit thin film transistor 121, high mobility is thereby realized with a large surface area. The arrangement of the readout circuit 120 and photodiode 110 on the entire display surface becomes possible.

### EXPLANATION OF REFERENCE NUMERALS

1 glass substrate
2 scanning electrode
3 signal readout electrode
3a metal source electrode
3b metal drain electrode
4 reference voltage portion
5 common electrode
11 first metal electrode
12 first semiconductor layer
13 first ohmic contact layer
14 first insulating layer
15 fifth insulating layer
16 first transparent electrode
16a first transparent electrode which is lower layer
16b first transparent electrode which is upper layer
17 second insulating layer
18 fourth transparent electrode
19 fourth metal electrode
21 second metal electrode
21a first gate electrode
21b second gate electrode
22 second semiconductor layer
23 second ohmic contact layer
24 third insulating layer
25 second removal portion
26 second transparent electrode
26a transparent source electrode
26b transparent drain electrode
27 fourth insulating layer
28 third metal electrode
29 third transparent electrode
100 two-dimensional photosensor
110 photodiode
120 readout circuit
121 signal readout circuit thin film transistor
130 gate driver
140 multiplexer
150 signal processing circuit
200 photosensing portion
L natural light
C1 first contact portion
C2 second contact portion
CE channel etching portion
RM1 insulating layer removal portion
S Schottky barrier section
Vb reference voltage

1. A two-dimensional photosensor comprising:
a plurality of arrayed photodiodes,
wherein the photodiodes each include:
a first metal electrode;
a first semiconductor layer;
a first ohmic contact layer; and
a first transparent electrode,
wherein the first semiconductor layer and the first ohmic contact layer are arranged between the first metal electrode and the first transparent electrode,
wherein a Schottky barrier is provided at an interface between the first semiconductor layer and the first metal electrode, or at an interface between the first semiconductor layer and the first transparent electrode, and
wherein the photosensor senses light incident from a side of the first transparent electrode toward the first semiconductor layer.

2. The two-dimensional photosensor according to claim 1, wherein the first semiconductor layer consists of amorphous silicon, and
wherein the first ohmic contact layer consists of n+ amorphous silicon.

3. The two-dimensional photosensor according to claim 1, wherein the first metal electrode has a light shielding property, and includes a configuration extending out of a light sensing region.

4. The two-dimensional photosensor according to claim 1, wherein photoelectric current of each of the photodiodes is individually acquired through direct connection, or acquired by scanning through a simple matrix system.

5. The two-dimensional photosensor according to claim 1, further comprising a readout circuit that reads a signal of the photodiode,
wherein the readout circuit includes a thin film transistor, and
wherein the thin film transistor includes at least one layer consisting of a layer which is the same as a layer constituting the photodiode.

6. The two-dimensional photosensor according to claim 5,
wherein the thin film transistor includes a second metal electrode,
wherein the second metal electrode functions as a gate electrode of the thin film transistor, and
wherein the second metal electrode consists of a layer which is the same as the first metal electrode of the photodiode, and is not electrically connected with the first metal electrode.

7. The two-dimensional photosensor according to claim S,
wherein the thin film transistor includes a source electrode and a drain electrode, and
wherein the source electrode and the drain electrode at least include a layer which is the same as the first transparent electrode possessed by the photodiode or the first metal electrode.

8. The two-dimensional photosensor according to claim 5,
wherein the thin film transistor includes a second semiconductor layer, and
wherein the second semiconductor layer consists of a layer which is the same as the first semiconductor layer possessed by the photodiode.

9. The two-dimensional photosensor according to claim 5, wherein the thin film transistor includes a second semiconductor layer consisting of indium gallium zinc oxide.

10. The two-dimensional photosensor according to claim 1, wherein the photodiode includes a dielectric layer which reduces surface reflection at a outermost surface on a side opposite to a glass substrate.

11. A manufacturing method of a two-dimensional photosensor,
the two-dimensional photosensor including
a plurality of arrayed photodiodes, and a readout circuit of signals from the photodiodes,
the photodiodes each including a laminate of
a first metal electrode,
a first semiconductor layer,
a first ohmic contact layer, and
a first transparent electrode,
wherein the first semiconductor layer and the first ohmic contact layer are arranged between the first metal electrode and the first transparent electrode,
a Schottky barrier is provided at an interface between the first semiconductor layer and the first metal electrode, or at an interface between the first semiconductor layer and the first transparent electrode,
the photosensor senses light incident from a side of the first transparent electrode toward the first semiconductor layer, and
the signal readout circuit includes a thin film transistor,
the method comprising a step of simultaneously forming at least one layer constituting the photodiode and the thin film transistor.

12. The manufacturing method of a two-dimensional photosensor according to claim 11,
wherein the thin film transistor includes:
a gate electrode;
a second semiconductor layer;
a second ohmic contact layer;
a source electrode and a drain electrode,
the method further comprising at least any one step among:
a metal electrode film forming step of simultaneously forming the first metal electrode and the gate electrode, or a metal electrode film forming step of simultaneously forming the first metal electrode, the source electrode and the drain electrode;
a semiconductor layer film forming step of simultaneously forming the first semiconductor layer and the second semiconductor layer;
an ohmic contact layer film forming step of simultaneously forming the first ohmic contact layer and the second ohmic contact layer; and
a transparent electrode film forming step of simultaneously forming the first transparent electrode, the source electrode and the drain electrode.

13. The manufacturing method of a two-dimensional photosensor according to claim 11, wherein the first semiconductor layer contains amorphous silicon, and the first ohmic contact layer contains n+ amorphous silicon.

14. The manufacturing method of a two-dimensional photosensor according to claim 11,
wherein the first semiconductor layer contains an amorphous silicon layer,
the first ohmic contact layer contains an n+ amorphous silicon layer,
the thin film transistor includes:
a second metal electrode arranged on a glass substrate, and functioning as a gate electrode;
a second semiconductor layer consisting of an IGZO layer; and
a second transparent electrode arranged on the second semiconductor layer, and functioning as a source electrode and a drain electrode,
the method further comprising:
a metal electrode film forming step of simultaneously forming the first metal electrode and the second metal electrode; and
a transparent electrode film forming step of simultaneously forming the first transparent electrode and the second transparent electrode.
